(19) United States
(12) Patent Application Publication
(10) Pub. No.: US 2008/0131722 A1
(43) Pub. Date: Jun. 5, 2008

(54) Single Layer Carbon Nanotube-Based Structures and Methods for Removing Heat from Solid-State Devices

(76) Inventors: Ephraim Suhir, Los Altos, CA (US); Subrata Dey, Fremont, CA (US); Barbara Wacker, Saratoga, CA (US); Peter Schwartz, Livermore, CA (US)

Correspondence Address: MORGAN, LEWIS & BOCKIUS, LLP., 2 PALO ALTO SQUARE, 3000 EL CAMINO REAL, PALO ALTO, CA, 94306, US

(21) Appl. No.: 11/749,126

(22) Filed: May 15, 2007

Related U.S. Application Data
(63) Continuation-in-part of application No. 11/498,408, filed on Aug. 2, 2006.
Application No. 11/498,408 is a continuation-in-part of application No. 11/386,254, filed on Mar. 21, 2006.
Application No. 11/386,254 is a continuation-in-part of application No. 11/618,441, filed on Dec. 29, 2006.
(60) Provisional application No. 60/800,935, filed on May 16, 2006.
(60) Provisional application No. 60/874,579, filed on Dec. 12, 2006.
(60) Provisional application No. 60/908,161, filed on Mar. 26, 2007.

(51) Int. Cl. B32B 15/04; H05K 3/00

(52) U.S. Cl. 428/616; 428/632; 428/634; 428/628; 428/629; 427/97.1

(57) ABSTRACT

One embodiment includes: a copper substrate; a catalyst on top of a single surface of the copper substrate; and a thermal interface material on top of the single surface of the copper substrate. The thermal interface material comprises: a layer of carbon nanotubes that contacts the catalyst, and a filler material located between the carbon nanotubes. The carbon nanotubes are oriented substantially perpendicular to the single surface of the copper substrate. The thermal interface material has: a bulk thermal resistance, a contact resistance between the thermal interface material and the copper substrate, and a contact resistance between the thermal interface material and a solid-state device. The summation of the bulk thermal resistance, the contact resistance between the thermal interface material and the copper substrate, and the contact resistance between the thermal interface material and the solid-state device has a value of 0.06 cm²K/W or less.

### RELATED APPLICATIONS

This application claims the benefit of: (A) U.S. Provisional Application No. 60/800,935, filed May 16, 2006, entitled “Small-size coupons and bonded assemblies for CNT-based thermal management of IC devices”; (B) U.S. Provisional Application No. 60/874,579, filed Dec. 12, 2006, entitled “Carbon nanotube-based structures and methods for removing heat from solid-state devices”; and (C) U.S. Provisional Application No. 60/908,161, filed Mar. 26, 2007, entitled “Single layer carbon nanotube-based structures and methods for removing heat from solid-state devices”. All of these applications are incorporated by reference herein in their entirety.

This application is a continuation-in-part of: (A) U.S. patent application Ser. No. 11/498,408, filed Aug. 2, 2006, which is a continuation of U.S. Pat. No. 7,109,581, filed Aug. 24, 2004, which in turn claims the benefit of U.S. Provisional Application No. 60/497,849 filed Aug. 25, 2003; (B) U.S. patent application Ser. No. 11/386,254, filed Mar. 21, 2006, entitled “Apparatus for attaching a cooling structure to an integrated circuit” which in turn claims the benefit of U.S. Provisional Application No. 60/663,225, filed Mar. 21, 2005; and (C) U.S. patent application Ser. No. 11/618,441, filed Dec. 29, 2006, entitled “Method and apparatus for the evaluation and improvement of mechanical and thermal properties of CNT/CNF arrays” which in turn claims the benefit of U.S. Provisional Application No. 60/862,664, filed Oct. 24, 2006. All of these applications are incorporated by reference herein in their entirety.

### TECHNICAL FIELD

The disclosed embodiments relate generally to structures and methods for removing heat from integrated circuits and other solid-state devices. More particularly, the disclosed embodiments relate to structures and methods that use carbon nanotubes to remove heat from integrated circuits and other solid-state devices.

### BACKGROUND

As the speed and density of modern integrated circuits (ICs) increase, the power generated by these chips also increases. The ability to dissipate the heat being generated by IC dies is becoming a serious limitation to advances in IC performance. Similar heat dissipation problems arise in other solid-state devices, such as light emitting diodes (LEDs), lasers, power transistors, RF devices, and solar cells.

Considerable effort has been put into developing materials and structures for use as thermal interface materials, heat spreaders, heat sinks, and other packaging components for ICs and solid-state devices, with limited success.

Thus, there remains a need to develop new structures and methods for removing heat from ICs and other solid-state devices that are compatible with current semiconductor packaging technology, provide low thermal resistances, and are low cost.

### SUMMARY

The present invention addresses the problems described above by providing carbon nanotube-based structures and methods for removing heat from IC dies and other solid-state devices.

One aspect of the invention involves an article of manufacture that includes: a copper substrate with a front surface and a back surface; a catalyst on top of a single surface of the copper substrate; and a thermal interface material on top of the single surface of the copper substrate. The thermal interface material comprises: a layer of carbon nanotubes that contacts the catalyst, and a filler material located between the carbon nanotubes. The carbon nanotubes are oriented substantially perpendicular to the single surface of the copper substrate. The thermal interface material has: a bulk thermal resistance, a contact resistance between the thermal interface material and the copper substrate, and a contact resistance between the thermal interface material and a solid-state device. The summation of the bulk thermal resistance, the contact resistance between the thermal interface material and the copper substrate, and the contact resistance between the thermal interface material and the solid-state device has a value of 0.06 cm²K/W or less.

Another aspect of the invention involves a method that includes forming a catalyst on top of a single surface of a copper substrate; growing a layer containing carbon nanotubes on the catalyst; and placing a filler material between carbon nanotubes in the layer containing carbon nanotubes. A thermal interface material comprises the layer containing carbon nanotubes and the filler material between carbon nanotubes. The thermal interface material has: a bulk thermal resistance, a contact resistance between the thermal interface material and the copper substrate, and a contact resistance between the thermal interface material and a solid-state device. The summation of the bulk thermal resistance, the contact resistance between the thermal interface material and the copper substrate, and the contact resistance between the thermal interface material and the solid-state device has a value of 0.06 cm²K/W or less.

Another aspect of the invention involves a method that includes: generating heat in a solid-state device; and conducting at least some of the heat away from the solid-state device via a thermal interface material in contact with the solid-state device. The thermal interface material is attached to a single surface of a copper substrate. The thermal interface material comprises: a layer of carbon nanotubes that are oriented substantially perpendicular to the single surface of the copper substrate, and a filler material located between the carbon nanotubes. The thermal interface material has: a bulk thermal resistance, a contact resistance between the thermal interface material and the copper substrate, and a contact resistance between the thermal interface material and the solid-state device. The summation of the bulk thermal resistance, the contact resistance between the thermal interface material and the copper substrate, and the contact resistance between the thermal interface material and the solid-state device has a value of 0.06 cm²K/W or less.

Another aspect of the invention involves an article of manufacture that includes: a heat spreader; a copper substrate with a front surface and a back surface, wherein the back surface is bonded to the heat spreader; and a thermal interface material attached to the front surface of the copper substrate comprising a layer of carbon nanotubes and a filler material located between the carbon nanotubes. The carbon nanotubes are oriented substantially perpendicular to the front surface of the copper substrate. The thermal interface material has: a bulk thermal resistance, a contact resistance between the thermal interface material and the copper substrate, and a contact resistance between the thermal interface material and a solid-state device. The summation of the bulk thermal resistance, the contact resistance between the thermal interface material and the copper substrate, and the contact resistance between the thermal interface material and the solid-state device has a value of 0.06 cm²K/W or less.

Another aspect of the invention involves a method that includes: growing a layer containing carbon nanotubes on top of a front surface of a copper substrate, wherein the layer of carbon nanotubes are oriented substantially perpendicular to the front surface of the copper substrate; bonding a back surface of the copper substrate to a heat spreader; and placing a filler material between carbon nanotubes in the layer containing carbon nanotubes. A thermal interface material comprises the layer containing carbon nanotubes and the filler material between carbon nanotubes. The thermal interface material has: a bulk thermal resistance, a contact resistance between the thermal interface material and the copper substrate, and a contact resistance between the thermal interface material and a solid-state device. The summation of the bulk thermal resistance, the contact resistance between the thermal interface material and the copper substrate, and the contact resistance between the thermal interface material and the solid-state device has a value of 0.06 cm²K/W or less.

Another aspect of the invention involves a method that includes bonding a back surface of a copper substrate to a heat spreader, wherein a thermal interface material is attached to a front surface of the copper substrate. The thermal interface material comprises: a layer of carbon nanotubes oriented substantially perpendicular to the front surface of the copper substrate, and a filler material between carbon nanotubes. The thermal interface material has: a bulk thermal resistance, a contact resistance between the thermal interface material and the copper substrate, and a contact resistance between the thermal interface material and a solid-state device. The summation of the bulk thermal resistance, the contact resistance between the thermal interface material and the copper substrate, and the contact resistance between the thermal interface material and the solid-state device has a value of 0.06 cm²K/W or less.

Another aspect of the invention involves a method that includes placing a filler material between carbon nanotubes in a layer containing carbon nanotubes to form a thermal interface material. The thermal interface material has: a bulk thermal resistance, a contact resistance between the thermal interface material and the copper substrate, and a contact resistance between the thermal interface material and a solid-state device. The summation of the bulk thermal resistance, the contact resistance between the thermal interface material and the copper substrate, and the contact resistance between the thermal interface material and the solid-state device has a value of 0.06 cm²K/W or less.

Another aspect of the invention involves an article of manufacture that includes: a solid-state device; a heat spreader; a copper substrate with a front surface and a back surface, wherein the back surface is bonded to the heat spreader; and a thermal interface material attached to the front surface of the copper substrate and contacting the solid-state device. The thermal interface material comprises a layer of carbon nanotubes and a filler material located between the carbon nanotubes. The carbon nanotubes are oriented substantially perpendicular to the front surface of the copper substrate. The thermal interface material has: a bulk thermal resistance, a contact resistance between the thermal interface material and the copper substrate, and a contact resistance between the thermal interface material and the solid-state device. The summation of the bulk thermal resistance, the contact resistance between the thermal interface material and the copper substrate, and the contact resistance between the thermal interface material and the solid-state device has a value of 0.06 cm²K/W or less.

Another aspect of the invention involves a method that includes contacting a solid-state device with a thermal interface material. The thermal interface material is attached to a single surface of a copper substrate. The copper substrate is attached to a surface of a heat spreader. The thermal interface material comprises: a layer of carbon nanotubes that are oriented substantially perpendicular to the surface of the heat spreader, and a filler material located between the carbon nanotubes. The thermal interface material has: a bulk thermal resistance, a contact resistance between the thermal interface material and the copper substrate, and a contact resistance between the thermal interface material and the solid-state device. The summation of the bulk thermal resistance, the contact resistance between the thermal interface material and the copper substrate, and the contact resistance between the thermal interface material and the solid-state device has a value of 0.06 cm²K/W or less.

Another aspect of the invention involves a method that includes generating heat in a solid-state device; conducting at least some of the heat away from the solid-state device via a thermal interface material in contact with the solid-state device; conducting at least some of the heat away via a copper substrate with a front surface in contact with the thermal interface material; and conducting at least some of the heat away via a heat spreader in contact with a back surface of the copper substrate. The thermal interface material comprises: a layer of carbon nanotubes that are oriented substantially perpendicular to the front surface of the copper substrate, and a filler material located between the carbon nanotubes. The thermal interface material has: a bulk thermal resistance, a contact resistance between the thermal interface material and the copper substrate, and a contact resistance between the thermal interface material and the solid-state device. The summation of the bulk thermal resistance, the contact resistance between the thermal interface material and the copper substrate, and the contact resistance between the thermal interface material and the solid-state device has a value of 0.06 cm²K/W or less.

Thus, the present invention provides carbon nanotube-based structures and methods that more efficiently remove heat from IC dies and other solid-state devices. Such structures and methods are compatible with current semiconductor packaging technology, provide low thermal resistances, and are low cost.

### BRIEF DESCRIPTION OF THE DRAWINGS

For a better understanding of the aforementioned aspects of the invention as well as additional aspects and embodiments thereof, reference should be made to the Description of Embodiments below, in conjunction with the following drawings in which like reference numerals refer to corresponding parts throughout the figures. For clarity, features in some figures are not drawn to scale.

FIGS. 1A & 1B are schematic cross sections of articles of manufacture in accordance with some embodiments.

FIG. 2 is a schematic drawing of a copper substrate with a thermal interface material that is configured to be bonded to a heat spreader in accordance with some embodiments.

FIG. 3 is a scanning electron microscope image of a layer containing carbon nanotubes in accordance with some embodiments.

FIG. 4A is a Raman spectrum of a layer containing carbon nanotubes in accordance with some embodiments.

FIG. 4B is a schematic diagram of the experimental configuration for obtaining the Raman spectra in FIGS. 4A, 4C &4D in accordance with some embodiments.

FIG. 4C is a plot of the Raman intensity ratio I_{D}/I_{G} versus thermal performance for layers containing carbon nanotubes, where I_{D} is the intensity of the D peak at ˜1350 cm⁻¹ and I_{G} is the intensity of the G peak at ˜1585 cm⁻¹, in accordance with some embodiments.

FIG. 4D shows Raman spectra of a layer containing carbon nanotubes with and without paraffin between the carbon nanotubes in accordance with some embodiments.

FIG. 5 is a schematic diagram of an experimental configuration for obtaining adhesion data in accordance with some embodiments.

FIG. 6 is a flow diagram illustrating one or more reliability tests that may be applied to carbon nanotube-based structures for removing heat in accordance with some embodiments.

FIG. 7 is a flow diagram illustrating a process for making a thermal interface material on a single side of a copper substrate in accordance with some embodiments.

FIG. 8 is a flow diagram illustrating a process for using a thermal interface material on a single side of a copper substrate in accordance with some embodiments.

FIG. 9 is a schematic cross section of an article of manufacture that includes a heat spreader with a thermal interface material on a copper substrate in accordance with some embodiments.

FIG. 10 is a flow diagram illustrating a process for making an article of manufacture that includes a heat spreader with a thermal interface material on a copper substrate in accordance with some embodiments.

FIG. 11A is a flow diagram illustrating a process for bonding a back surface of a copper substrate to a heat spreader in accordance with some embodiments.

FIG. 11B is a flow diagram illustrating a process for bonding a back surface of a copper substrate to a heat spreader in accordance with some embodiments.

FIG. 12A-12D are flow diagrams illustrating processes for placing a filler material between carbon nanotubes in a layer containing carbon nanotubes to form a thermal interface material in accordance with some embodiments.

FIG. 13 illustrates a side view of an article of manufacture that includes a solid-state device (e.g., an integrated circuit) and a heat spreader with a thermal interface material on a copper substrate in accordance with some embodiments.

FIG. 14A is a flow diagram illustrating a process for contacting a solid state-device (e.g., an integrated circuit) with a thermal interface material in accordance with some embodiments.

FIG. 14B is a flow diagram illustrating a process for contacting an integrated circuit with a thermal interface material in accordance with some embodiments.

FIG. 15 is a flow diagram illustrating a process for removing heat from a solid state-device (e.g., an integrated circuit) in accordance with some embodiments.

### DESCRIPTION OF EMBODIMENTS

Carbon nanotube-based structures and methods for removing heat from ICs and other solid-state devices are described. As used in the specification and claims, “carbon nanotubes” include carbon nanotubes of varying structural quality, from carbon nanotubes with few defects to carbon nanotubes with many defects (the latter of which are sometimes referred to in the art as “carbon nanofibers”). Thus, as used herein, “carbon nanotubes” include “carbon nanofibers.” Reference will be made to certain embodiments of the invention, examples of which are illustrated in the accompanying drawings. While the invention will be described in conjunction with the embodiments, it will be understood that it is not intended to limit the invention to these particular embodiments alone. On the contrary, the invention is intended to cover alternatives, modifications and equivalents that are within the spirit and scope of the invention as defined by the appended claims.

Moreover, in the following description, numerous specific details are set forth to provide a thorough understanding of the present invention. However, it will be apparent to one of ordinary skill in the art that the invention may be practiced without these particular details. In other instances, methods, procedures, and components that are well known to those of ordinary skill in the art are not described in detail to avoid obscuring aspects of the present invention.

It will be understood that when a layer is referred to as being “on top of” another layer, it can be directly on the other layer or intervening layers may also be present. In contrast, when a layer is referred to as “contacting” another layer, there are no intervening layers present.

It will also be understood that, although the terms first, second, etc. may be used herein to describe various elements, these elements should not be limited by these terms. These terms are only used to distinguish one element from another. For example, a first layer could be termed a second layer, and, similarly, a second layer could be termed a first layer, without departing from the scope of the present invention.

Furthermore, relative terms, such as “lower” or “bottom” and “upper” or “top,” may be used herein to describe one element's relationship to another element as illustrated in the figures. It will be understood that relative terms are intended to encompass different orientations of the device in addition to the orientation depicted in the figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The present invention is described below with reference to block diagrams and/or flowchart illustrations of systems, devices, and/or methods according to embodiments of the invention. It should be noted that in some alternate implementations, the functions/acts noted in the blocks may occur out of the order noted in the flowcharts. For example, two blocks shown in succession may in fact be executed substantially concurrently or the blocks may sometimes be executed in the reverse order, depending upon the functionality/acts involved.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. Thus, the regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. It will be further understood that terms, such as those defined in commonly used dictionaries, should be interpreted as having a meaning that is consistent with their meaning in the present specification and in the context of the relevant art and will not be interpreted in an idealized or overly formal sense unless expressly so defined herein. All publications, patent applications, patents, and other references mentioned herein are incorporated by reference in their entirety.

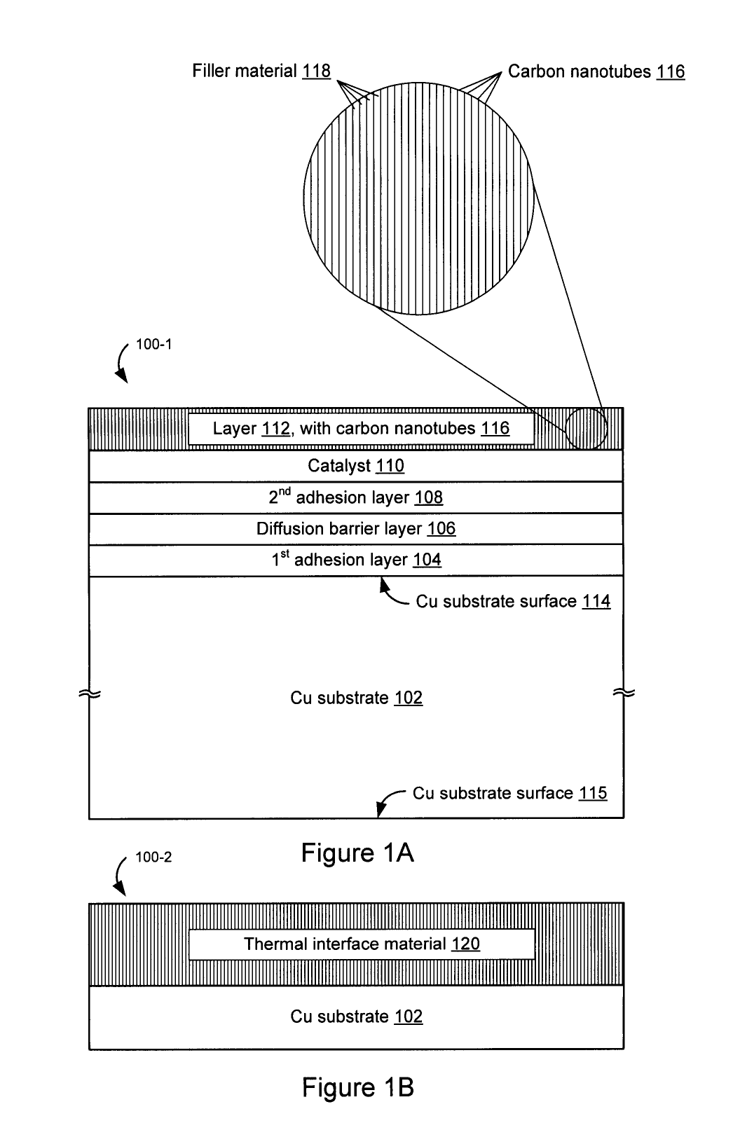

FIGS. 1A & 1B are schematic cross sections of articles of manufacture 100 in accordance with some embodiments.

The articles of manufacture 100 comprise a copper substrate 102 with a front surface (e.g., 114) and a back surface (e.g., 115). The copper substrate may be pure copper (e.g., electrical copper with at least 99.99% purity) or a copper alloy. In some embodiments, the copper substrate 102 contains less than 40 parts per million (ppm) oxygen. In some embodiments, the copper substrate 102 contains 10 ppm oxygen or less. In some embodiments, the copper substrate is oxygen-free copper (OFC). We have found that reducing the amount of oxygen in the substrate increases the uniformity of the carbon nanotubes that are subsequently grown on top of the substrate.

For clarity, the thicknesses of the layers in FIG. 1A are not drawn to scale. The thin films between the layer 112 containing carbon nanotubes 116 and the copper substrate 102 (e.g., first adhesion layer 104, diffusion barrier layer 106, second adhesion layer 108, and catalyst 110) are much thinner than the layer 112 containing carbon nanotubes 116 and the copper substrate 102. These thin films are not shown in FIG. 1B.

Thermal interface material 120 includes the layer 112 with carbon nanotubes 116 and a filler material 118 located between the carbon nanotubes (e.g. a wax, an ester, an acrylate, a phase change material, or mixtures thereof). Thermal interface material 120 may be thicker or thinner than the copper substrate 102.

Thermal interface material 120 is on top of a single surface of the copper substrate 102 (e.g., Cu substrate surface 114, FIG. 1A, but not also Cu substrate 115). The single surface may be the front surface of the Cu substrate 102 or the back surface of the Cu substrate 102, but not both surfaces simultaneously. Embodiments (not shown) in which the thermal interface material is on top of both surfaces of the Cu substrate 102 (i.e., both the front surface of the Cu substrate 102 and the back surface of the Cu substrate 102) are beyond the scope of the present invention.

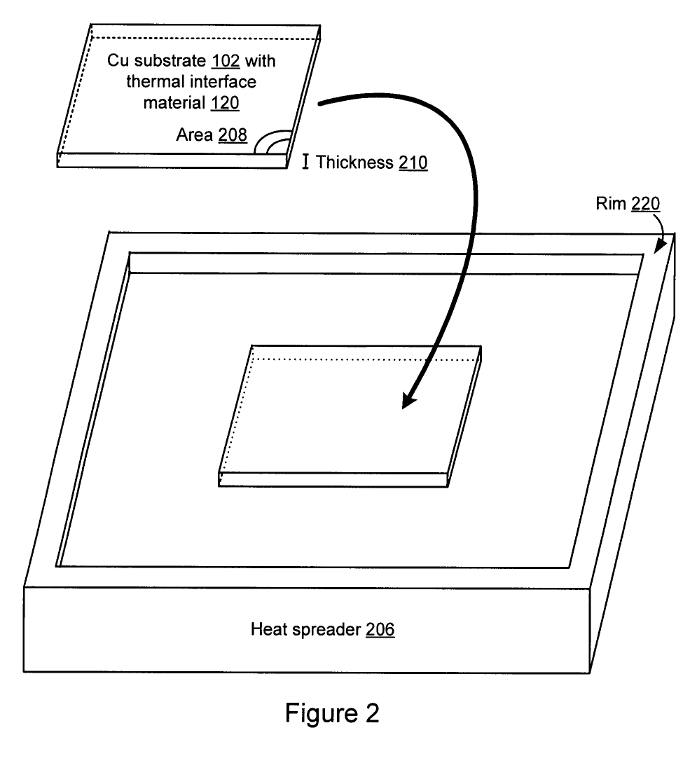

FIG. 2 is a schematic drawing of a copper substrate 102 with a thermal interface material 120 that is configured to be bonded to a heat spreader 206 in accordance with some embodiments.

In some embodiments, the copper substrate 102 has a typical area 208 ranging from 49 mm² (e.g., 7 mm×7 mm) to 2500 mm² (e.g., 50 mm×50 mm). In some embodiments, the copper substrate 102 has a thickness 210 between 5 microns and 1 mm. In some embodiments, the copper substrate 102 has a thickness 210 between 5 and 100 microns. In some embodiments, the copper substrate 102 has a thickness 210 between 5 and 25 microns. Thinner copper substrates 102 may simplify the manufacture of heat spreaders and other cooling structures by eliminating the need to make a recessed cavity in the heat spreader to accommodate the copper substrate 102. In some embodiments, the heat spreader 206 is made of copper, a copper alloy, nickel-plated copper, or another high thermal conductivity substrate with a melting point above 900° C. (e.g., CuW, SiC, AlN, or graphite). In some embodiments, the heat spreader 206 does not have a rim 220.

In some embodiments, the copper substrate 102 has a cross-sectional area 208 that substantially corresponds to the cross-sectional area of an integrated circuit or other solid-state device (e.g., a light emitting diode, laser, power transistor, RF device, or solar cell). Thus, the area of thermal interface material 120 formed on the copper substrate 102 can be tailored to the corresponding area of an integrated circuit or other solid-state device that will contact the thermal interface material 120.

In some embodiments, the article of manufacture 100 includes a first adhesion layer 104 that contacts the surface 114 of the copper substrate 102. The first adhesion layer helps keep subsequent layers firmly attached to the copper substrate. In some embodiments, the first adhesion layer 104 has a thickness between 200 and 5000 Å and comprises Ti, TiN, Cr, or Ta. In some embodiments, the first adhesion layer 104 has a thickness between 200 and 500 Å and comprises Ti.

In some embodiments, the article of manufacture 100 includes a diffusion barrier layer 106 on top of the first adhesion layer 104. The diffusion barrier layer minimizes diffusion of a catalyst 110 into the copper substrate during subsequent high-temperature processing (e.g., during nanotube growth). In some embodiments, the diffusion barrier layer 106 has a thickness between 100 and 400 Å and comprises TiN, SiO₂, Al₂O₃, or TaN. In some embodiments, the diffusion barrier layer 106 has a thickness between 100 and 400 Å and comprises TiN.

In some embodiments, the article of manufacture 100 includes a second adhesion layer 108 between the diffusion barrier layer 106 and the catalyst 110. Although not required, the second adhesion layer promotes adhesion of the catalyst 110 during subsequent high-temperature processing (e.g., during nanotube growth), when thermal stresses create nucleation sites in the catalyst 110. In some embodiments, the second adhesion layer 108 has a thickness between 25 and 400 Å and comprises Ti, SiO₂, TiN, Al₂O₃, or Mo. In some embodiments, the second adhesion layer 108 has a thickness between 25 and 200 Å and comprises Ti.

The article of manufacture 100 includes a catalyst 110 on top of the copper substrate surface 114. As the name implies, the catalyst catalyzes growth of the carbon nanotubes. The catalyst is deposited as a layer. The catalyst layer may subsequently form catalyst particles that act as carbon nanotube nucleation sites during the process used to form carbon nanotubes. In some embodiments, the as-deposited catalyst 110 has a thickness between 30 and 1000 Å and comprises Ni, Fe, or Co. In some embodiments, the as-deposited catalyst 110 has a thickness between 200 and 400 Å and comprises Ni.

The article of manufacture 100 also includes a layer 112 containing carbon nanotubes 116 that contacts the catalyst 110. The carbon nanotubes 116 are oriented substantially perpendicular to the surface 114 of the copper substrate. This orientation minimizes the thermal resistance of the layer 112 and of thermal interface materials 120 that include the layer 112. In some embodiments, the carbon nanotubes 116 comprise multiwalled carbon nanotubes.

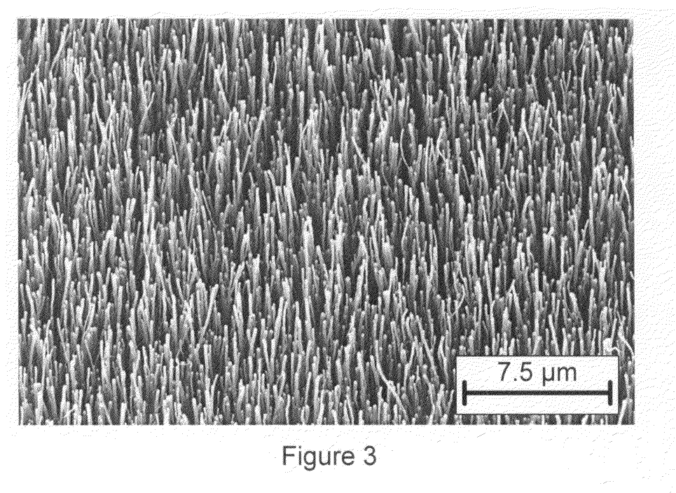

FIG. 3 is a scanning electron microscope image of a layer 112 containing carbon nanotubes 116 in accordance with some embodiments.

In some embodiments, the carbon nanotubes 116 have an average diameter between 60 nm and 200 nm. In some embodiments, the carbon nanotubes have an average diameter between 100 nm and 150 nm. In some embodiments, the carbon nanotubes 116 have an average length between 5 and 50 μm. In some embodiments, the carbon nanotubes have an average length between 20 and 45 μm. In some embodiments, the carbon nanotubes 116 have a tip density between 10 and 40 nanotubes per μm². In some embodiments, the carbon nanotubes 116 have a surface area coverage density between 15 and 40 percent.

In some embodiments, substantially all (e.g., >85%) of the carbon nanotubes 116 are individually separated from each other. Although axial thermal conduction of carbon nanotubes is very high, lateral thermal conduction (in the non-axial direction from nanotube to nanotube) is not as good. In fact, it has been found that lateral contact between axially aligned nanotubes can reduce their effective axial thermal conductivity. If the number of carbon nanotubes attached to substrate is too high (for example, >40% carbon nanotube density) Van der Waals forces will create a bundle or mat situation resulting in poor thermal conduction. If, on the other hand the coverage density is too low (for example, <15%), thermal conduction will also be lower due to the reduced number of conducting nanotubes. A preferred range a coverage density is between about 15 and 40%, with 25 to 40% being most preferred. Thus, vertically aligned, individually separated, parallel carbon nanotubes with coverage between about 15 and 40%, may provide better overall thermal conduction than a bundle or mat of carbon nanotubes.

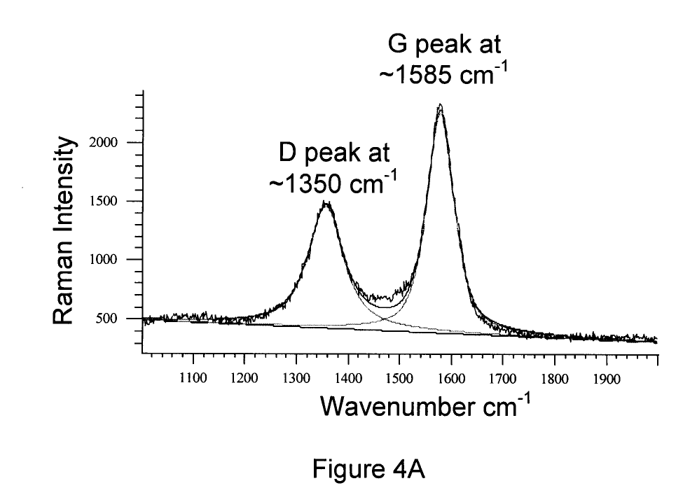

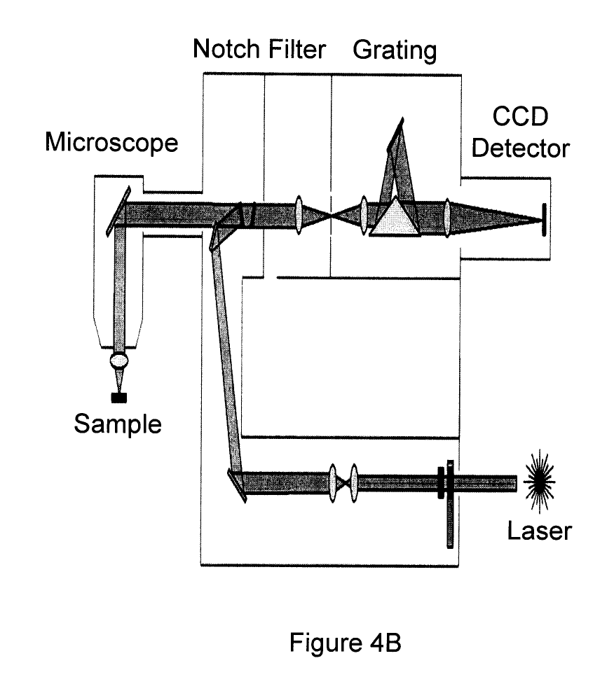

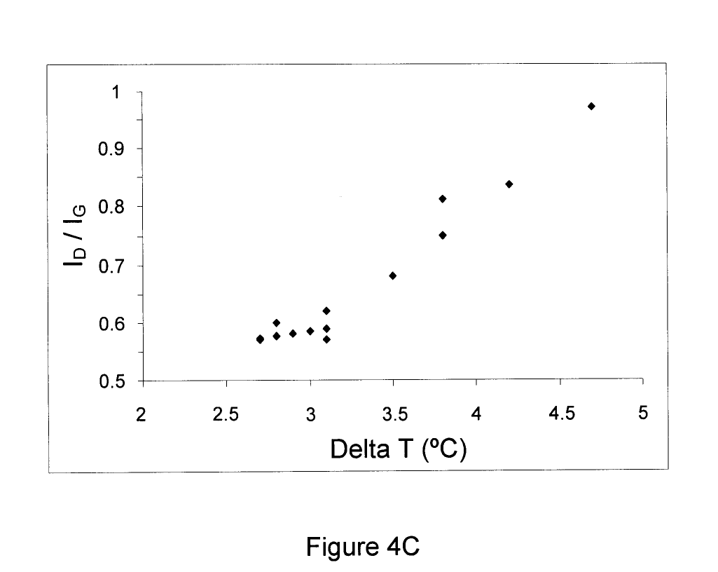

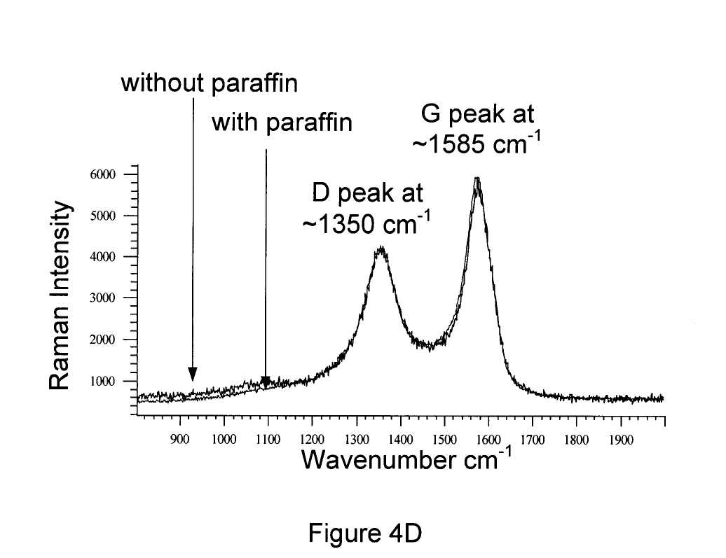

FIG. 4A is a Raman spectrum of a layer containing carbon nanotubes in accordance with some embodiments. The Raman spectrum of the layer 112 containing carbon nanotubes 116 has a D peak at ˜1350 cm⁻¹ with an intensity I_{D} and a G peak at ˜1585 cm⁻¹ with an intensity I_{G}.

FIG. 4B is a schematic diagram of the experimental configuration for obtaining the Raman spectra in FIGS. 4A, 4C & 4D in accordance with some embodiments. A Renishaw in Via Raman microscope with a 514 nm laser beam was used to obtain the Raman spectra. A ˜10 mW, ˜10 μm² laser spot was directed onto the sample with a 50× objective lens. The laser spot was configured to hit the carbon nanotubes in a direction that was parallel to the axes of the carbon nanotubes. The Raman spectra were analyzed using Renishaw WiRE 2.0 software.

FIG. 4C is a plot of the Raman intensity ratio I_{D}/I_{G} versus thermal performance for layers containing carbon nanotubes, in accordance with some embodiments. We have found that the thermal performance of the layer containing carbon nanotubes depends strongly on the quality of the nanotubes grown, which, in turn, depends on the materials, layers, and growth conditions used. As shown in FIG. 4C, we have also found that Raman spectra from the layer of carbon nanotubes can be used to monitor the quality of the nanotubes. We have found that layers 112 with an intensity ratio I_{D}/I_{G} of less than 0.7 at a laser excitation wavelength of 514 nm provide good thermal performance (e.g., 0.08 cm²K/W or less for a 0.8 mm thick Cu substrate with layer 112, as described below), with an intensity ratio I_{D}/I_{G} of less than 0.6 at a laser excitation wavelength of 514 nm being preferred. In FIG. 4C, the intensity ratio I_{D}/I_{G} is plotted versus the temperature drop (Delta T, ° C.) across an ASTM D 5470 thermal interface material tester containing identical copper substrates with different layers of carbon nanotubes. As shown in FIG. 4C, the temperature drop decreases (which corresponds to lower thermal resistance) as the I_{D}/I_{G} intensity ratio decreases.

The Raman measurements may be taken with no interstitial (i.e., filler) material 118 between the nanotubes (e.g., before a phase change material is placed between the carbon nanotubes or after such a phase change material is removed from between the carbon nanotubes).

The Raman measurements may also be taken with an interstitial material between the nanotubes if the interstitial material does not interfere with the D peak at ˜1350 cm⁻¹ and the G peak at ˜1585 cm⁻¹. For example, FIG. 4D shows Raman spectra of a layer containing carbon nanotubes with and without paraffin between the carbon nanotubes in accordance with some embodiments. The D and G peaks in the two spectra and the corresponding I_{D}/I_{G} intensity ratios are essentially the same.

In some embodiments, a 0.8 mm thick copper substrate 102 with a thermal interface material 120 comprising: (a) the layer 112 containing carbon nanotubes 116 (with an average length of 25-45 μm) and (b) paraffin wax has a thermal resistance of 0.08 cm²K/W or less. This thermal resistance is a summation of: (1) the bulk thermal resistance of the copper substrate 102 (0.02 cm²K/W for a 0.8 mm thick copper substrate), (2) the contact resistance between the thermal interface material 120 and the copper substrate 102, (3) the bulk thermal resistance of the thermal interface material 120, and (4) the contact resistance between the thermal interface material 120 and an integrated circuit or other solid-state device. Thus, the summation of (2)-(4) (i.e., the bulk thermal resistance of the thermal interface material and the two contact resistances associated with the thermal interface material) is 0.06 cm²K/W or less. In some embodiments, for a thermal interface material comprising (a) the layer 112 containing carbon nanotubes 116 and (b) paraffin wax, the sum of the bulk thermal resistance of the thermal interface material and the two contact resistances associated with the thermal interface material is 0.03 cm²K/W or less. In some embodiments, the sum of the bulk thermal resistance of the thermal interface material and the two contact resistances associated with the thermal interface material is 0.02 cm²K/W or less. In some embodiments, the sum of the bulk thermal resistance of the thermal interface material and the two contact resistances associated with the thermal interface material is between 0.02-0.06 cm²K/W. These values are better than what is achieved with conventional thermal interface materials and with prior thermal interface materials that include a layer of carbon nanotubes on a single surface of a copper substrate.

In some embodiments, a 25 μm thick copper substrate 102 with a thermal interface material 120 comprising: (a) the layer 112 containing carbon nanotubes 116 (e.g., with an average length of 25-45 μm) and (b) filler material 118 (e.g. a wax, an ester, an acrylate, a phase change material, or mixtures thereof) has a thermal resistance of 0.06 cm²K/W or less. This thermal resistance is a summation of: (1) the bulk thermal resistance of the copper substrate 102 (0.0006 cm²K/W for a 25 μm thick copper substrate), (2) the contact resistance between the thermal interface material 120 and the copper substrate 102, (3) the bulk thermal resistance of the thermal interface material 120, and (4) the contact resistance between the thermal interface material 120 and a solid-state device (e.g., an IC) or the equivalent of a solid-state device for testing purposes (e.g., a thermal testing vehicle (TTV) or a heated copper block). Thus, the summation of (2)-(4) (i.e., the bulk thermal resistance of the thermal interface material and the two contact resistances associated with the thermal interface material) is 0.06 cm²K/W or less. In some embodiments, the sum of the bulk thermal resistance of the thermal interface material and the two contact resistances associated with the thermal interface material is 0.03 cm²K/W or less. In some embodiments, the sum of the bulk thermal resistance of the thermal interface material and the two contact resistances associated with the thermal interface material is 0.02 cm²K/W or less. In some embodiments, the sum of the bulk thermal resistance of the thermal interface material and the two contact resistances associated with the thermal interface material is between 0.02-0.06 cm²K/W. These values are better than what is achieved with conventional thermal interface materials and with prior thermal interface materials that include a layer of carbon nanotubes on a single surface of a copper substrate.

In testing thermal interface materials, the “solid-state device” referred to in the phrase “contact resistance between the thermal interface material and a/the solid-state device” may be a thermal test vehicle (TTV, e.g., a non-functional IC package that uses one or more heater resistors to simulate the power dissipation of a live IC), a heated copper block (e.g., in an ASTM D 5470 thermal interface material tester), or other equivalent to a solid-state device for testing purposes. Thus, in the specification and claims, the “contact resistance between the thermal interface material and a/the solid-state device” includes the contact resistance between the thermal interface material and a solid-state device (e.g., an IC, light emitting diode, laser, power transistor, RF device, or solar cell), a TTV, a copper block in a thermal interface material tester, or other equivalents to a solid-state device for testing purposes.

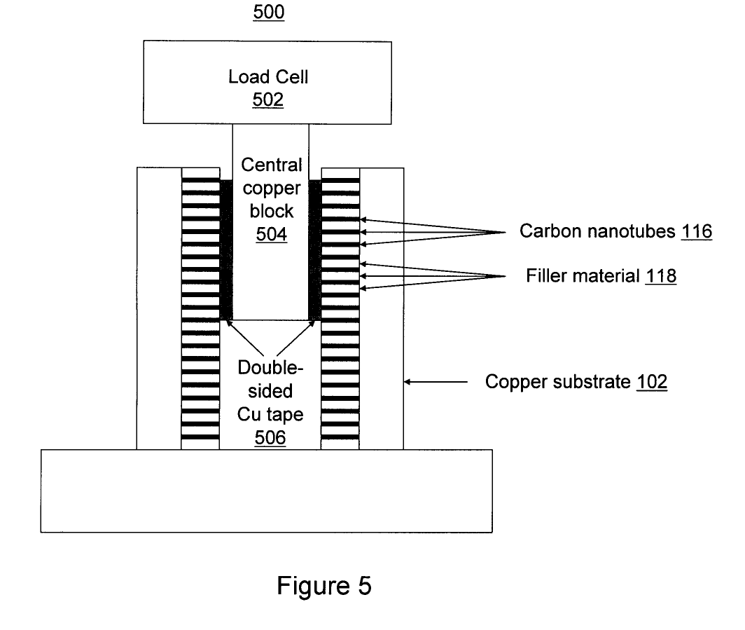

FIG. 5 is a schematic diagram of an experimental configuration 500 for obtaining adhesion data in accordance with some embodiments.

Two samples of thermal interface materials 120 (comprising a layer 112 of carbon nanotubes 116 and filler material 118) on copper substrates 102 are attached (e.g., with double sided copper tape 506) to a central copper block 504 in a load cell 502. For a 2 cm×2 cm sample, the tape 506 is typically attached to a 1 cm×2 cm portion of the sample (e.g., the upper half of the samples in FIG. 5). A shearing force is applied by moving the central copper block 504 vertically. The layer 112 of carbon nanotubes 116 is attached to the copper substrate 102. The shearing force needed to detach the layer of carbon nanotubes from the copper substrate is measured.

In some embodiments, the layer of carbon nanotubes can withstand a shearing force of at least 0.5 Kgf without detaching from the copper substrate. In some embodiments, the layer of carbon nanotubes can withstand a shearing force of at least 3.3 Kgf without detaching from the copper substrate. In some embodiments, the layer of carbon nanotubes can withstand a shearing force of at least 5 Kgf without detaching from the copper substrate.

The interfacial shearing stress (adhesion) required to detach the layer of carbon nanotubes from the copper substrate may be calculated using the formula:

τₘₐₓ=kT

where τₘₐₓ is the interfacial shear stress (adhesion), k is a constant equal to 0.0422 mm⁻², and T is the measured shearing force required for detachment. Adhesion measurements are discussed in greater detail in U.S. patent application Ser. No. 11/618,441, filed Dec. 29, 2006, entitled “Method and apparatus for the evaluation and improvement of mechanical and thermal properties of CNT/CNF arrays.”

In some embodiments, the layer of carbon nanotubes can withstand an interfacial shearing stress of at least 30 psi without detaching from the copper substrate. In some embodiments, the layer of carbon nanotubes can withstand an interfacial shearing stress of at least 200 psi without detaching from the copper substrate. In some embodiments, the layer of carbon nanotubes can withstand an interfacial shearing stress of at least 300 psi without detaching from the copper substrate.

We have found that adhesion of the layer containing carbon nanotubes correlates with the overall thermal performance of the thermal interface material. For example, the value of the summation of the bulk thermal resistance and the two contact resistances associated with the thermal interface material is typically greater than 0.10 cm²K/W if the layer of carbon nanotubes fails a tape pull test, whereas the value of the summation is 0.06 cm²K/W or less if the layer of carbon nanotubes passes a tape pull test.

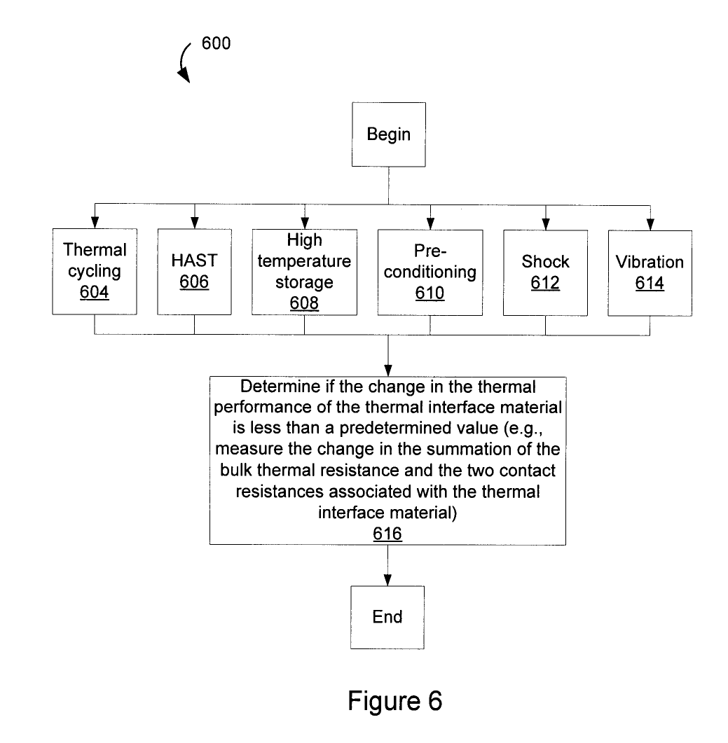

FIG. 6 is a flow diagram illustrating one or more reliability tests that may be applied to carbon nanotube-based structures for removing heat in accordance with some embodiments. It is desirable that carbon nanotube-based structures maintain their thermal performance after being exposed or subjected to harsh environments. These environments may include one or more of:
Temperature cycling 604 (e.g., as described in Joint Electron Device Engineering Council (JEDEC) Standard JESD22-A 104C);
Highly-accelerated temperature and humidity stressing (HAST) 606 (e.g., as described in JEDEC Standard JESD22-A100-B);
High temperature storage 608 (e.g., as described in JEDEC Standard JESD22-A103C);
Preconditioning of non-hermetic surface mount devices prior to reliability testing 610 (e.g., as described in JEDEC Standard JESD22A113E);
Mechanical shock 612 (e.g. as described in Military Standard (MIL-STD) 883E, method 2002.3, test condition B); and/or
Vibration 614 (e.g., variable frequency vibration as described in MIL-STD 883E, method 2007.2, test condition A and/or random vibration as described in JEDEC Standard JESD22-B103-B, test condition D).

It is desirable that the thermal interface material 120 maintains its overall thermal performance. For example, the value of the summation of the bulk thermal resistance and the two contact resistances associated with the thermal interface material should change (e.g., increase) by less than a predetermined value (e.g., 5%, 10%, or 15%) after an article containing a thermal interface material is subjected to one or more of these environments. The two contact resistances associated with the thermal interface material are the contact resistance between the thermal interface material and the copper substrate, and the contact resistance between the thermal interface material and a solid-state device (e.g., an IC) or the equivalent of a solid-state device for testing purposes (e.g., a TTV or a copper block, as discussed above).

In some embodiments, for the thermal interface material 120, the value of the summation of the bulk thermal resistance, the contact resistance between the thermal interface material and the copper substrate, and the contact resistance between the thermal interface material and the solid-state device changes by less than 15% when the article of manufacture is cycled from −40° C. to 125° C. with a 25° C./min ramp and 5 minute dwell times for 1000 cycles. In some embodiments, the value of the summation changes by less than 10%.

In some embodiments, for the thermal interface material 120, the value of the summation of the bulk thermal resistance, the contact resistance between the thermal interface material and the copper substrate, and the contact resistance between the thermal interface material and the solid-state device changes by less than 15% when the article of manufacture is heated at 120° C. for 96 hours in 85% relative humidity. In some embodiments, the value of the summation changes by less than 10%.

In some embodiments, for the thermal interface material 120, the value of the summation of the bulk thermal resistance, the contact resistance between the thermal interface material and the copper substrate, and the contact resistance between the thermal interface material and the solid-state device changes by less than 15% when the article of manufacture is heated at 150° C. for 1000 hours. In some embodiments, the value of the summation changes by less than 10%.

In some embodiments, for the thermal interface material 120, the value of the summation of the bulk thermal resistance, the contact resistance between the thermal interface material and the copper substrate, and the contact resistance between the thermal interface material and the solid-state device changes by less than 15% when the article of manufacture is: cycled from −40° C. to 125° C. with a 10° C./min ramp and 10 minute dwell times for 5 cycles, then heated at 125° C. for 24 hours, then heated at 30° C. for 192 hours in 60% relative humidity, and then cycled from 25° C. (room temperature) to 260° C. for 3 cycles. In some embodiments, the value of the summation changes by less than 10%.

In some embodiments, for the thermal interface material 120, the value of the summation of the bulk thermal resistance, the contact resistance between the thermal interface material and the copper substrate, and the contact resistance between the thermal interface material and the solid-state device changes by less than 15% when the article of manufacture is subjected to variable frequency vibration from 20 Hz to 2000 Hz with a peak acceleration of 20 G (e.g., 4 4-minute cycles from 20 Hz to 2000 Hz and back to 20 Hz performed in each of three orthogonal orientations (total of 12 times), so that the motion is applied for a total period of not less than 48 minutes). In some embodiments, the value of the summation changes by less than 10%.

In some embodiments, for the thermal interface material 120, the value of the summation of the bulk thermal resistance, the contact resistance between the thermal interface material and the copper substrate, and the contact resistance between the thermal interface material and the solid-state device changes by less than 15% when the article of manufacture is subjected to Gaussian random vibration with 1.11 G root mean square (RMS) acceleration, 1.64 in/sec RMS velocity, 0.0310 inches RMS displacement, and 0.186 three sigma peak-to-peak displacement for 30 minutes in each of three orthogonal axes. In some embodiments, the value of the summation changes by less than 10%.

In some embodiments, for the thermal interface material 120, the value of the summation of the bulk thermal resistance, the contact resistance between the thermal interface material and the copper substrate, and the contact resistance between the thermal interface material and the solid-state device changes by less than 15% when the article of manufacture is subjected to a mechanical shock of 1500 G in a 0.5 ms, half sine wave pulse, with 5 such shocks applied along 6 different axes. In some embodiments, the value of the summation changes by less than 10%.

Prior to this invention, carbon nanotube-based thermal interface materials had not been reported that could maintain their thermal performance in one or more of the environments described above.

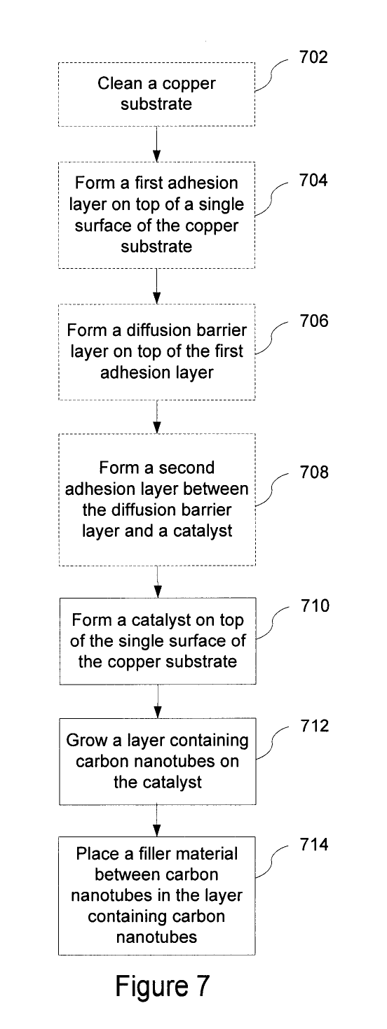

FIG. 7 is a flow diagram illustrating a process for making a thermal interface material on a single side of a copper substrate in accordance with some embodiments.

In some embodiments, a copper substrate 102 is cleaned (702). In some embodiments, the copper substrate 102 is an oxygen-free copper substrate.

In some embodiments, cleaning the copper substrate 102 comprises exposing the substrate 102 to a wet chemical bath. In some embodiments, the wet chemical bath comprises citric acid. In some embodiments, the wet chemical bath is a 100:1 mixture of 5% citric acid and hydrogen peroxide.

In some embodiments, cleaning the copper substrate 102 comprises sputter cleaning the copper substrate.

In some embodiments, a plasma etch step is used to remove contaminants from the copper substrate 102.

We have found that using an oxygen-free copper substrate and thoroughly cleaning the substrate to remove grease, oxides, and other contaminants greatly increases the uniformity and quality of the subsequently grown layer of carbon nanotubes.

Using a copper substrate that can be bonded after nanotube growth to a heat spreader enables a layer of carbon nanotubes to be grown on the copper substrate in an optimum manner, without concern for how the nanotube growth conditions may alter the dimensions, surfaces, and/or mechanical properties of the heat spreader.

In some embodiments, a first adhesion layer 104 is formed (704) on top of a single surface of the copper substrate 102 (e.g., surface 114, FIG. 1A).

In some embodiments, a diffusion barrier layer 106 is formed (706) on top of the first adhesion layer 104.

In some embodiments, a second adhesion layer 108 is formed (708) between the diffusion barrier layer 106 and the catalyst 110. In some embodiments, the second adhesion layer 108 is formed by sputtering.

A catalyst 110 is formed (710) on top of the single surface of the copper substrate 102 (e.g., surface 114, FIG. 1A).

In some embodiments, the first adhesion layer 104, the diffusion barrier layer 106, the second adhesion layer 108, and the catalyst 10 are formed by sputtering. In some embodiments, the first adhesion layer 104, the diffusion barrier layer 106, the second adhesion layer 108, and the catalyst 110 are formed by sequentially sputtering each respective layer.

If there is no second adhesion layer, in some embodiments, the first adhesion layer 104, the diffusion barrier layer 106, and the catalyst 110 are formed by sputtering. If there is no second adhesion layer, in some embodiments, the first adhesion layer 104, the diffusion barrier layer 106, and the catalyst 110 are formed by sequentially sputtering each respective layer.

Other deposition methods, such as electron beam evaporation, may be used to form the first adhesion layer 104, the diffusion barrier layer 106, the second adhesion layer 108, and/or the catalyst 110. The uniformity and thickness of each of these layers, especially the catalyst 110, is preferably kept within 10% total variation to promote a uniform catalyst nucleation process, which promotes individual separation of carbon nanotubes in the layer 112 containing carbon nanotubes. In some embodiments, the uniformity and thickness of the catalyst 110 is kept within 5% total variation.

A layer 112 containing carbon nanotubes is grown (712) on the catalyst 110. As is known in the art, carbon nanotubes may form via either tip growth or base growth on the catalyst. As used in the specification and claims, growing carbon nanotubes “on the catalyst” includes tip growth, base growth, or mixtures thereof.

In some embodiments, growing the layer containing carbon nanotubes comprises a temperature ramp in an inert atmosphere followed by nanotube growth in a carbon-containing atmosphere.

In some embodiments, the temperature ramp includes ramping the temperature between 600 and 800° C. in 5 minutes or less. In some embodiments, the temperature ramp includes ramping the temperature between 600 and 800° C. in 2 minutes or less. We have found that a fast temperature ramp between 600 and 800° C. promotes a uniform catalyst nucleation process, which promotes individual separation of carbon nanotubes in the layer 112 containing carbon nanotubes.

In some embodiments, the inert atmosphere comprises argon or nitrogen.

In some embodiments, nanotube growth in the carbon-containing atmosphere comprises plasma-enhanced chemical vapor deposition (PECVD) of carbon nanotubes. In some embodiments, the PECVD comprises flowing NH₃ and C₂H₂ gases over the catalyst at a temperature between 700 and 900° C. in a total pressure between 1 and 10 torr. In some embodiments, the total pressure is between 2 and 4 torr. An electric field created by a DC plasma may be used to align the carbon nanotubes during the PECVD growth process. In some embodiments, nanotube growth in the carbon-containing atmosphere comprises thermal chemical vapor deposition (CVD) of carbon nanotubes. In some embodiments, the thermal CVD comprises flowing NH₃ and C₂H₂ gases over the catalyst at a temperature between 700 and 900° C. in a total pressure between 1 and 10 torr. In some embodiments, the total pressure is between 2 and 4 torr. For both PECVD and thermal CVD, we have found that using NH₃ and a total pressure between 1 and 10 torr improves the quality of the nanotubes and their adhesion to the copper substrate.

In some embodiments, the carbon nanotubes are annealed after the growth process to release thermal stresses and to remove defects in the nanotube layer (e.g., at temperatures ranging from 700° C. to 1000° C.).

In some embodiments, a Raman spectrum of the layer containing carbon nanotubes has a D peak at ˜1350 cm⁻¹ with an intensity I_{D}, a G peak at ˜1585 cm⁻¹ with an intensity I_{G}, and an intensity ratio I_{D}/I_{G} of less than 0.7 at a laser excitation wavelength of 514 nm. In some embodiments, the intensity ratio I_{D}/I_{G} is less than 0.6.

A filler material is placed (714) between carbon nanotubes in the layer containing carbon nanotubes. In some embodiments, the filler material has one or more of the following properties:
Viscosity between 0.5-100 cSt (at 25° C.), typically 10 cSt—for rapid uptake in the layer containing carbon nanotubes;
Melting point between 30-120° C., preferably between 40-80° C., and most preferably between 50-60° C.;
Thermal conductivity between 0.1-500 W/m° K, typically between 0.2-10 W/m° K;
Modulus between 50-1000 psi, preferably between 50-150 psi—for better compliance of the thermal interface material;
Boiling point of at least 250° C.;
Surface tension between 1-100 dyne/cm, preferably between 1-20 dynes/cm—with lower values preferred so that the filler material wets the carbon nanotubes.

In some embodiments, the filler material comprises an ester, such as Purester 40 (CH₃—(CH₂)₂₀—COO—(CH₂)₁₇—CH₃, an ester made from stearyl alcohol and methyl behenate by Strahl & Pitsch, http://www.spwax.com/sppure.htm). In some embodiments, the filler material comprises a wax, such as MULTIWAX® W445 Multicrystalline Wax from Gehring-Montgomery, Inc. (http://gehring-montgomery.com/pdfs/MICROCRY.pdf) or paraffin (e.g., C44 paraffin). In some embodiments, the filler material comprises an acrylate. In some embodiments, the filler material comprises a mixture of acrylates. In some embodiments, the filler material comprises a mixture of methyl acrylate, octadecyl acrylate, and acrylic acid. In some embodiments, the filler material comprises a mixture of 0-50% methyl acrylate, 50-90% octadecyl acrylate, and 0-10% acrylic acid. In some embodiments, the filler material comprises a mixture of 27% methyl acrylate, 70% octadecyl acrylate, and 3% acrylic acid. (The preceding percentages are volume percentages.) In some embodiments, the filler material comprises mixtures of esters, waxes, and/or acrylates. In some embodiments, the filler material comprises a conductive filler such as graphene, which may be combined with an ester, wax, and/or acrylate. In some embodiments, the filler material comprises an antioxidant, such as 2′,3-bis[[3-[3,5-di-tert-butyl-4-hydroxyphenyl]propionyl]]propionohydrazide (which goes by the trade name Ciba® IRGANOX® MD 1024) or Pentaerythritol Tetrakis(3-(3,5-di-tert-butyl-4-hydroxyphenyl)propionate) (which goes by the trade name Ciba® IRGANOX® 1010). In some embodiments, between 0.5-5% antioxidant improves the long term stability of the filler material.

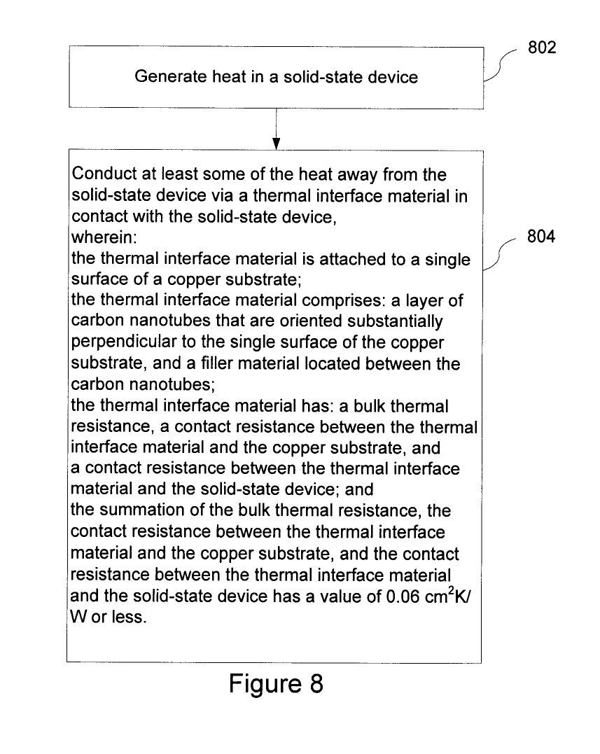

FIG. 8 is a flow diagram illustrating a process for using a thermal interface material 120 on a single side of a copper substrate in accordance with some embodiments.

Heat is generated (802) in a solid-state device. In some embodiments, the solid-state device is an integrated circuit.

At least some of the heat is conducted (804) away from the solid-state device via a thermal interface material in contact with the solid-state device. The thermal interface material is attached to a single surface of a copper substrate. The thermal interface material comprises: a layer of carbon nanotubes that are oriented substantially perpendicular to the single surface of the copper substrate, and a filler material located between the carbon nanotubes. The thermal interface material has: a bulk thermal resistance, a contact resistance between the thermal interface material and the copper substrate, and a contact resistance between the thermal interface material and the solid-state device. The summation of the bulk thermal resistance, the contact resistance between the thermal interface material and the copper substrate, and the contact resistance between the thermal interface material and the solid-state device has a value of 0.06 cm²K/W or less. In some embodiments, the summation of the bulk thermal resistance, the contact resistance between the thermal interface material and the copper substrate, and the contact resistance between the thermal interface material and the solid-state device has a value of 0.03 cm²K/W or less. In some embodiments, the summation of the bulk thermal resistance, the contact resistance between the thermal interface material and the copper substrate, and the contact resistance between the thermal interface material and the solid-state device has a value of 0.02 cm²K/W or less. In some embodiments, the summation of the bulk thermal resistance, the contact resistance between the thermal interface material and the copper substrate, and the contact resistance between the thermal interface material and the solid-state device has a value between 0.02-0.06 cm²K/W. These values are better than what is achieved with conventional thermal interface materials and with prior thermal interface materials that include a layer of carbon nanotubes on a single surface of a copper substrate.

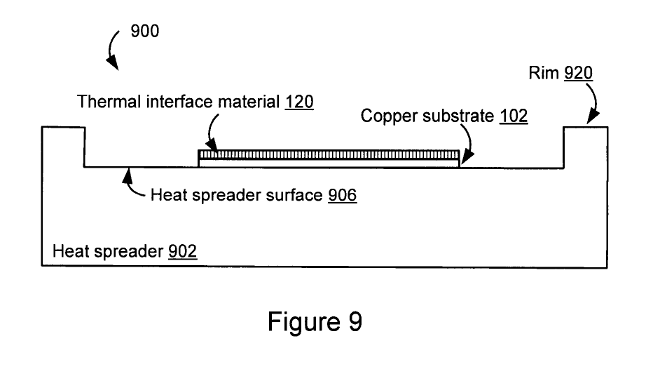

FIG. 9 is a schematic cross section of an article of manufacture 900 that includes a heat spreader 902 with a thermal interface material 120 on a copper substrate 102 in accordance with some embodiments.

In some embodiments, the heat spreader 902 does not have a rim 920. In some embodiments, the heat spreader 900 comprises copper or other high-thermal conductivity metal. The copper may comprise pure copper, an alloy containing copper, a mixture containing copper (e.g., Cu—W), and/or a composite containing copper (e.g., Cu—Mo laminate).

The heat spreader 902 has a surface 906 that is configured to face an integrated circuit or other solid-state device.

The copper substrate 102 has a front surface and a back surface. The back surface is bonded to the heat spreader. In some embodiments, the copper substrate has a thickness between 5 microns and 1 mm. In some embodiments, the copper substrate has a thickness between 5 and 100 microns. In some embodiments, the copper substrate has a thickness between 5 and 25 microns.

The thermal interface material 120 is attached to the front surface of the copper substrate. The thermal interface material 120 comprises a layer 112 of carbon nanotubes 116 and a filler material 118 located between the carbon nanotubes. The carbon nanotubes 116 are oriented substantially perpendicular to the front surface of the copper substrate. In some embodiments, substantially all of the carbon nanotubes are individually separated from each other.

In some embodiments, a Raman spectrum of the layer of carbon nanotubes has a D peak at ˜1350 cm⁻¹ with an intensity I_{D}, a G peak at ˜1585 cm⁻¹ with an intensity I_{G}, and an intensity ratio I_{D}/I_{G} of less than 0.7 at a laser excitation wavelength of 514 nm. In some embodiments, the intensity ratio I_{D}/I_{G} is less than 0.6.

In some embodiments, the layer 112 of carbon nanotubes 116 are attached to the front surface of the copper substrate 102 by growing the carbon nanotubes on the front surface of the copper substrate. In some embodiments, as described above, the layer of carbon nanotubes can withstand a shearing force of at least 0.5 Kgf without detaching from the copper substrate. In some embodiments, the layer of carbon nanotubes can withstand a shearing force of at least 3.3 Kgf without detaching from the copper substrate. In some embodiments, the layer of carbon nanotubes can withstand a shearing force of at least 5 Kgf without detaching from the copper substrate.

In some embodiments, as described above, the layer of carbon nanotubes can withstand an interfacial shearing stress of at least 30 psi without detaching from the copper substrate. In some embodiments, the layer of carbon nanotubes can withstand an interfacial shearing stress of at least 200 psi without detaching from the copper substrate. In some embodiments, the layer of carbon nanotubes can withstand an interfacial shearing stress of at least 300 psi without detaching from the copper substrate.

In some embodiments, the filler material 118 located between the carbon nanotubes comprises a phase change material. In some embodiments, the filler material located between the carbon nanotubes comprises an ester, a wax, or an acrylate. In some embodiments, the phase change material comprises paraffin. We believe that filler materials like paraffin improve the thermal performance of the thermal interface material 120 by filling the air gap between carbon nanotubes with lengths that do not make thermal contact with an opposing IC or other solid-state device surface and by wetting and separating the carbon nanotubes when pressed to conform with asperities on the opposing surface.

In some embodiments, as described above, the filler material comprises an ester, such as Purester 40 (CH₃—(CH₂)₂₀—COO—(CH₂)₁₇—CH₃, an ester made from stearyl alcohol and methyl behenate by Strahl & Pitsch, http://www.spwax.com/sppure.htm). In some embodiments, the filler material comprises a wax, such as MULTIWAX® W445 Multicrystalline Wax from Gehring-Montgomery, Inc. (http://gehring-montgomery.com/pdfs/MICROCRY.pdf) or paraffin (e.g., C44 paraffin). In some embodiments, the filler material comprises an acrylate. In some embodiments, the filler material comprises a mixture of acrylates. In some embodiments, the filler material comprises a mixture of methyl acrylate, octadecyl acrylate, and acrylic acid. In some embodiments, the filler material comprises a mixture of 0-50% methyl acrylate, 50-90% octadecyl acrylate, and 0-10% acrylic acid. In some embodiments, the filler material comprises a mixture of 27% methyl acrylate, 70% octadecyl acrylate, and 3% acrylic acid. (The preceding percentages are volume percentages.) In some embodiments, the filler material comprises mixtures of esters, waxes, and/or acrylates. In some embodiments, the filler material comprises a conductive filler such as graphene, which may be combined with an ester, wax, and/or acrylate. In some embodiments, the filler material comprises an antioxidant, such as 2′,3-bis[[3-[3,5-di-tert-butyl-4-hydroxyphenyl]propionyl]]propionohydrazide (which goes by the trade name Ciba® IRGANOX® MD 1024) or Pentaerythritol Tetrakis(3-(3,5-di-tert-butyl-4-hydroxyphenyl)propionate) (which goes by the trade name Ciba® IRGANOX® 1010). In some embodiments, between 0.5-5% antioxidant improves the long term stability of the filler material.

The thermal interface material has: a bulk thermal resistance, a contact resistance between the thermal interface material and the front surface of the copper substrate, and a contact resistance between the thermal interface material and a solid-state device. The summation of the bulk thermal resistance, the contact resistance between the thermal interface material and the copper substrate, and the contact resistance between the thermal interface material and the solid-state device has a value of 0.06 cm²K/W or less. In some embodiments, the summation has a value of 0.03 cm²K/W or less. In some embodiments, the summation has a value of 0.02 cm²K/W or less. In some embodiments, the summation has a value between 0.02-0.06 cm²K/W. These values are better than what is achieved with conventional thermal interface materials and with prior thermal interface materials that include a layer of carbon nanotubes on a single surface of a copper substrate.

In some embodiments, as described above with respect to FIG. 6, the value of the summation of the bulk thermal resistance and the two contact resistances associated with the thermal interface material changes (e.g., increases) by less than a predetermined value (e.g., 5%, 10%, or 15%) after an article containing the thermal interface material is subjected to one or more harsh environments (e.g., thermal cycling 604, HAST 606, high temperature storage 608, preconditioning 610, shock 612, and/or vibration 614). The two contact resistances associated with the thermal interface material are the contact resistance between the thermal interface material and the copper substrate, and the contact resistance between the thermal interface material and a solid-state device (e.g., an IC) or the equivalent of a solid-state device for testing purposes (e.g., a TTV or a copper block, as discussed above).

The article of manufacture 900 may be reworkable, which increases yields and reduces manufacturing costs. In some embodiments, an integrated circuit or other solid-state device may be removably connected to the thermal interface material 120. In some embodiments, the thermal interface material 120 is configured to enable an integrated circuit or other solid-state device to be connected to the thermal interface material, disconnected from the thermal interface material, and then reconnected to the thermal interface material. In some embodiments, the article of manufacture 900 is configured to be reused to cool a succession of integrated circuits or other solid-state devices.

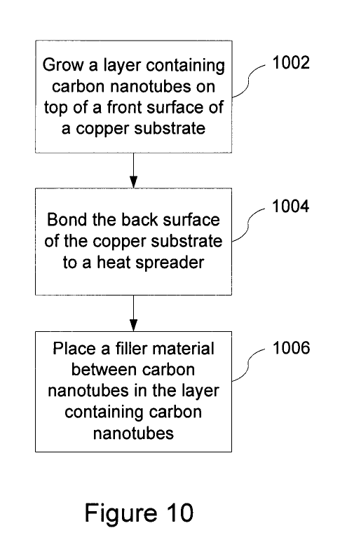

FIG. 10 is a flow diagram illustrating a process for making an article of manufacture 900 that includes a heat spreader 902 with a thermal interface material 120 on a copper substrate 102 in accordance with some embodiments.

A layer 112 containing carbon nanotubes 116 is grown (1002) on top of a front surface (e.g., 114) of a copper substrate 102 (e.g., as described above with respect to FIG. 7). The layer of carbon nanotubes are oriented substantially perpendicular to the front surface of the copper substrate.

In some embodiments, a Raman spectrum of the layer of carbon nanotubes has a D peak at ˜1350 cm⁻¹ with an intensity I_{D}, a G peak at ˜1585 cm⁻¹ with an intensity I_{G}, and an intensity ratio I_{D}/I_{G} of less than 0.7 at a laser excitation wavelength of 514 nm. In some embodiments, the intensity ratio I_{D}/I_{G} is less than 0.6 at a laser excitation wavelength of 514 nm.

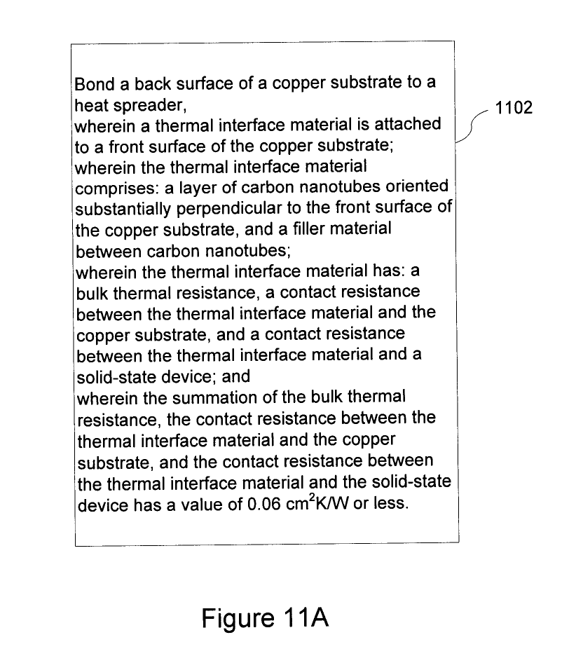

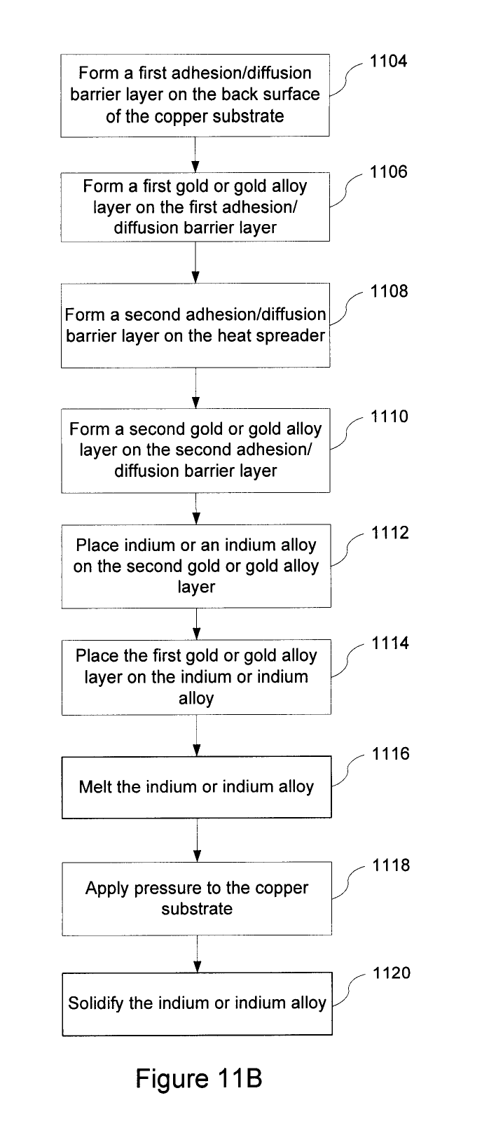

A back surface (e.g., 115) of the copper substrate is bonded (1004) to a heat spreader 902. In some embodiments, bonding the back surface of the copper substrate to a heat spreader comprises the process discussed below with respect to FIG. 11B.

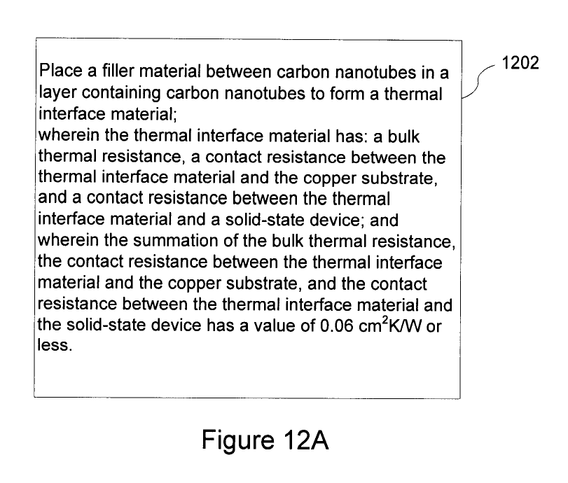

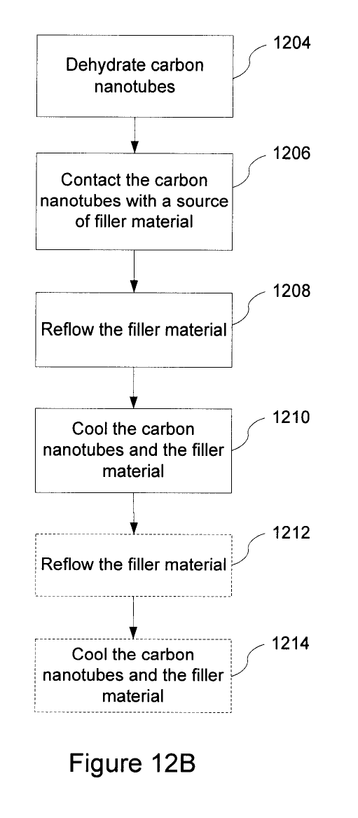

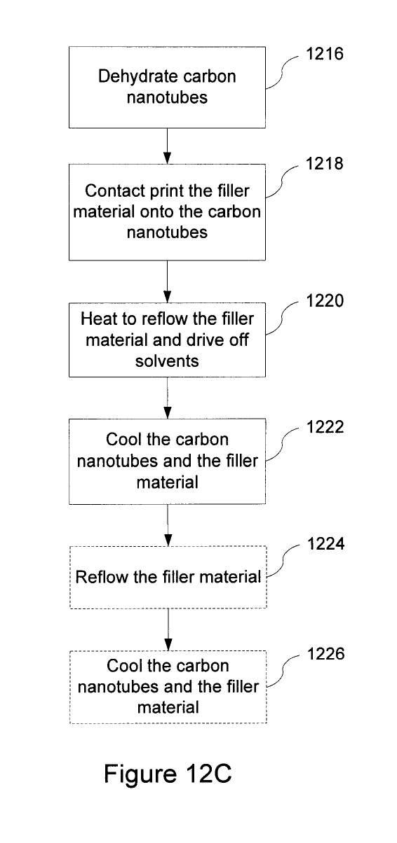

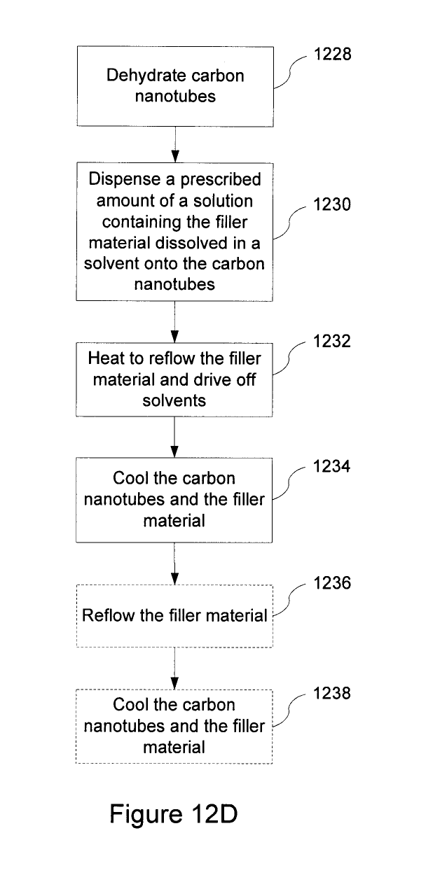

A filler material 118 is placed (1006) between carbon nanotubes in the layer 112 containing carbon nanotubes 116. In some embodiments, the filler material comprises an ester, a wax, an acrylate, or mixtures thereof, as described above. In some embodiments, placing a filler material between carbon nanotubes in the layer containing carbon nanotubes comprises the process discussed below with respect to FIG. 12B, the process discussed below with respect to FIG. 12C, or the process discussed below with respect to FIG. 12D.

A thermal interface material comprises the layer 112 containing carbon nanotubes 116 and the filler material 118 between carbon nanotubes. The thermal interface material has: a bulk thermal resistance, a contact resistance between the thermal interface material and the copper substrate 102, and a contact resistance between the thermal interface material and a solid-state device. The summation of the bulk thermal resistance, the contact resistance between the thermal interface material and the copper substrate, and the contact resistance between the thermal interface material and the solid-state device has a value of 0.06 cm²K/W or less. In some embodiments, the summation has a value of 0.03 cm²K/W or less. In some embodiments, the summation has a value of 0.02 cm²K/W or less. In some embodiments, the summation has a value between 0.02-0.06 cm²K/W. These values are better than what is achieved with conventional thermal interface materials and with prior thermal interface materials that include a layer of carbon nanotubes on a single surface of a copper substrate.

FIG. 11A is a flow diagram illustrating a process for bonding (1102) a back surface (e.g., 115) of a copper substrate 102 to a heat spreader 902 in accordance with some embodiments.

A thermal interface material 120 is attached to a front surface (e.g., 114) of the copper substrate 102. The thermal interface material comprises: a layer 112 of carbon nanotubes 116 oriented substantially perpendicular to the front surface of the copper substrate, and a filler material 118 between carbon nanotubes.

The thermal interface material has: a bulk thermal resistance, a contact resistance between the thermal interface material and the copper substrate 102, and a contact resistance between the thermal interface material and a solid-state device. The summation of the bulk thermal resistance, the contact resistance between the thermal interface material and the copper substrate, and the contact resistance between the thermal interface material and the solid-state device has a value of 0.06 cm²K/W or less. In some embodiments, the summation has a value of 0.03 cm²K/W or less. In some embodiments, the summation has a value of 0.02 cm²K/W or less. In some embodiments, the summation has a value between 0.02-0.06 cm²K/W. These values are better than what is achieved with conventional thermal interface materials and with prior thermal interface materials that include a layer of carbon nanotubes on a single surface of a copper substrate.

FIG. 11B is a flow diagram illustrating a process for bonding a back surface (e.g., 115) of a copper substrate 102 to a heat spreader 902 in accordance with some embodiments. In some embodiments, the bonding comprises:

forming (1104) a first adhesion/diffusion barrier layer on the back surface of the copper substrate (e.g., by sputtering or electron evaporation);

forming (1106) a first gold or gold alloy layer on the first adhesion/diffusion barrier layer (e.g., by sputtering or electron evaporation);

forming (1108) a second adhesion/diffusion barrier layer on the heat spreader (e.g., by sputtering or electron evaporation);

forming (1110) a second gold or gold alloy layer on the second adhesion/diffusion barrier layer (e.g., by sputtering or electron evaporation);

placing (1112) indium or an indium alloy on the second gold or gold alloy layer (e.g., a 25 μm thick indium foil for a 25 μm bond line thickness);

placing (1114) the first gold or gold alloy layer on the indium or indium alloy; melting (1116) the indium or indium alloy;

applying (1118) pressure to the copper substrate (e.g., applying 2-5 lb. pressure); and

solidifying (1120) the indium or indium alloy (e.g., by cooling to room temperature).

In some embodiments, the first adhesion/diffusion barrier layer has a thickness between 1500 and 5000 Å and comprises TiW. In some embodiments, the first adhesion/diffusion barrier layer has a thickness between 2500 and 3000 Å and comprises TiW (e.g., 10% Ti, 90% W).

In some embodiments, the first gold or gold alloy layer has a thickness between 2000 and 5000 Å. In some embodiments, the first gold or gold alloy layer has a thickness between 4000 and 5000 Å.

In some embodiments, the second adhesion/diffusion barrier layer has a thickness between 1500 and 5000 Å and comprises TiW. In some embodiments, the second adhesion/diffusion barrier layer has a thickness between 2500 and 3000 Å and comprises TiW (e.g., 10% Ti, 90% W).

In some embodiments, the second gold or gold alloy layer has a thickness between 2000 and 5000 Å. In some embodiments, the second gold or gold alloy layer has a thickness between 4000 and 5000 Å.

In some embodiments, the indium or indium alloy has a thickness between 10 and 50 μm. In some embodiments, the indium or indium alloy has a thickness between 10 and 20 μm.

In some embodiments, the bonding comprises microwave bonding (e.g., as disclosed in U.S. Pat. Nos. 6,734,409 and 6,809,305), tin-lead solder bonding, or reactive bonding (e.g., as disclosed in U.S. Pat. No. 5,381,944).

FIG. 12A is a flow diagram illustrating a process for placing (1202) a filler material 118 between carbon nanotubes 116 in a layer 112 containing carbon nanotubes to form a thermal interface material 120 in accordance with some embodiments.

The thermal interface material 120 has: a bulk thermal resistance, a contact resistance between the thermal interface material and the copper substrate, and a contact resistance between the thermal interface material and a solid-state device. The summation of the bulk thermal resistance, the contact resistance between the thermal interface material and the copper substrate, and the contact resistance between the thermal interface material and the solid-state device has a value of 0.06 cm²K/W or less. In some embodiments, the summation has a value of 0.03 cm²K/W or less. In some embodiments, the summation has a value of 0.02 cm²K/W or less. In some embodiments, the summation has a value between 0.02-0.06 cm²K/W. These values are better than what is achieved with conventional thermal interface materials and with prior thermal interface materials that include a layer of carbon nanotubes on a single surface of a copper substrate.

In some embodiments, as described above with respect to FIG. 6, the value of the summation of the bulk thermal resistance and the two contact resistances associated with the thermal interface material changes (e.g., increases) by less than a predetermined value (e.g., 5%, 10%, or 15%) after an article containing the thermal interface material is subjected to one or more harsh environments (e.g., thermal cycling 604, HAST 606, high temperature storage 608, preconditioning 610, shock 612, and/or vibration 614). The two contact resistances associated with the thermal interface material are the contact resistance between the thermal interface material and the copper substrate, and the contact resistance between the thermal interface material and a solid-state device (e.g., an IC) or the equivalent of a solid-state device for testing purposes (e.g. a TTV or a copper block, as discussed above).

In some embodiments, a Raman spectrum of the layer containing carbon nanotubes has a D peak at ˜1350 cm⁻¹ with an intensity I_{D}, a G peak at ˜1585 cm⁻¹ with an intensity I_{G}, and an intensity ratio I_{D}/I_{G} of less than 0.7 at a laser excitation wavelength of 514 nm. In some embodiments, the intensity ratio I_{D}/I_{G} is less than 0.6.

FIG. 12B is a flow diagram illustrating a process for placing a filler material 118 between carbon nanotubes 116 in a layer 112 containing carbon nanotubes to form a thermal interface material 120 in accordance with some embodiments. In some embodiments, the placing comprises:

dehydrating (1204) the carbon nanotubes (e.g., by placing an article with the layer containing carbon nanotubes on a heated surface at 100° C. for 5 minutes);

contacting (1206) the carbon nanotubes with a source of filler material (e.g., for paraffin wax, pressing a pre-waxed paper on to the tips of the carbon nanotubes with a flat surface at a temperature above the melting point of the paraffin wax);

reflowing (1208) the filler material;

cooling (1210) the carbon nanotubes and filler material (e.g., by quenching on a metal block); and

optionally, reflowing (1212) the filler material again and cooling (1214) the carbon nanotubes and filler material one or more additional times.

FIG. 12C is a flow diagram illustrating a process for placing a filler material 118 between carbon nanotubes 116 in a layer 112 containing carbon nanotubes to form a thermal interface material 120 in accordance with some embodiments. In some embodiments, the placing comprises:

dehydrating (1216) the carbon nanotubes (e.g., by placing an article with the layer containing carbon nanotubes on a heated surface at 100° C. for 5 minutes);

contact printing (1218) the filler material onto the carbon nanotubes (e.g., using a silicon stamp and a filler material reservoir to transfer a prescribed amount of filler material from the stamp to the carbon nanotubes);

heating (1220) to reflow the filler material and drive off solvents (e.g., in a vacuum oven);

cooling (1222) the carbon nanotubes and filler material (e.g., by quenching on a metal block); and

optionally, reflowing (1224) the filler material again and cooling (1226) the carbon nanotubes and filler material one or more additional times.

FIG. 12D is a flow diagram illustrating a process for placing a filler material 118 between carbon nanotubes 116 in a layer 112 containing carbon nanotubes to form a thermal interface material 120 in accordance with some embodiments. In some embodiments, the placing comprises:

dehydrating (1228) the carbon nanotubes (e.g., by placing an article with the layer containing carbon nanotubes on a heated surface at 100° C. for 5 minutes);

dispensing (1230) a prescribed amount of a solution containing the filler material dissolved in a solvent (e.g., a solution containing the filler material and the solvent in a ratio between 1:10 and 1:500) onto the carbon nanotubes;

heating (1232) to reflow the filler material and drive off solvents (e.g., in a vacuum oven);

cooling (1234) the carbon nanotubes and filler material (e.g., by quenching on a metal block); and

optionally, reflowing (1236) the filler material again and cooling (1238) the carbon nanotubes and filler material one or more additional times.

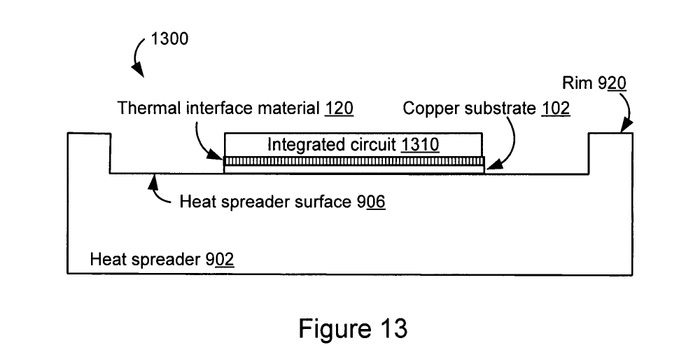

FIG. 13 illustrates a side view of an article of manufacture 1300 that comprises a solid-state device (e.g., integrated circuit 1310) and a heat spreader 902 with a thermal interface material 120 on a copper substrate 102 in accordance with some embodiments. The printed circuit board or other substrate that the integrated circuit 1310 is attached to is omitted for clarity. Article 1300 can further include additional components (not shown).

The copper substrate 102 has a front surface (e.g., 114) and a back surface (e.g., 115). The back surface is bonded to the heat spreader 902. The heat spreader 902 has a surface 906 facing the integrated circuit 1310.

The thermal interface material 120 is attached to the front surface of the copper substrate and contacts the solid-state device. In some embodiments, the solid-state device is an integrated circuit (e.g., IC 1310).

The thermal interface material 120 comprises a layer 112 of carbon nanotubes 116 and a filler material 118 located between the carbon nanotubes. The layer 112 of carbon nanotubes is attached to the copper substrate 102. The carbon nanotubes are oriented substantially perpendicular to the front surface of the copper substrate.

The thermal interface material 120 has: a bulk thermal resistance, a contact resistance between the thermal interface material and the copper substrate, and a contact resistance between the thermal interface material and the solid-state device. The summation of the bulk thermal resistance, the contact resistance between the thermal interface material and the copper substrate, and the contact resistance between the thermal interface material and the solid-state device has a value of 0.06 cm²K/W or less. In some embodiments, the summation has a value of 0.03 cm²K/W or less. In some embodiments, the summation has a value of 0.02 cm²K/W or less. In some embodiments, the summation has a value between 0.02-0.06 cm²K/W. These values are better than what is achieved with conventional thermal interface materials and with prior thermal interface materials that include a layer of carbon nanotubes on a single surface of a copper substrate.

In some embodiments, as described above with respect to FIG. 6, the value of the summation of the bulk thermal resistance and the two contact resistances associated with the thermal interface material changes (e.g., increases) by less than a predetermined value (e.g., 5%, 10%, or 15%) after an article containing the thermal interface material is subjected to one or more harsh environments (e.g., thermal cycling 604, HAST 606, high temperature storage 608, preconditioning 610, shock 612, and/or vibration 614). The two contact resistances associated with the thermal interface material are the contact resistance between the thermal interface material and the copper substrate, and the contact resistance between the thermal interface material and a solid-state device (e.g., an IC) or the equivalent of a solid-state device for testing purposes (e.g. a TTV or a copper block, as discussed above).

In some embodiments, the copper substrate has a thickness between 5 microns and 1 mm. In some embodiments, the copper substrate has a thickness between 5 and 100 microns. In some embodiments, the copper substrate has a thickness between 5 and 25 microns.

In some embodiments, the filler material 118 located between the carbon nanotubes comprises a phase change material. In some embodiments, the filler material 118 located between the carbon nanotubes comprises an ester, a wax, or an acrylate.

In some embodiments, as described above, the filler material comprises an ester, such as Purester 40 (CH₃—(CH₂)₂₀—COO—(CH₂)₁₇—CH₃, an ester made from stearyl alcohol and methyl behenate by Strahl & Pitsch, http://www.spwax.com/sppure.htm). In some embodiments, the filler material comprises a wax, such as MULTIWAX® W445 Multicrystalline Wax from Gehring-Montgomery, Inc. (http://gehring-montgomery.com/pdfs/MICROCRY.pdf) or paraffin (e.g., C44 paraffin). In some embodiments, the filler material comprises an acrylate. In some embodiments, the filler material comprises a mixture of acrylates. In some embodiments, the filler material comprises a mixture of methyl acrylate, octadecyl acrylate, and acrylic acid. In some embodiments, the filler material comprises a mixture of 0-50% methyl acrylate, 50-90% octadecyl acrylate, and 0-10% acrylic acid. In some embodiments, the filler material comprises a mixture of 27% methyl acrylate, 70% octadecyl acrylate, and 3% acrylic acid. (The preceding percentages are volume percentages.) In some embodiments, the filler material comprises mixtures of esters, waxes, and/or acrylates. In some embodiments, the filler material comprises a conductive filler such as graphene, which may be combined with an ester, wax, and/or acrylate. In some embodiments, the filler material comprises an antioxidant, such as 2′,3-bis[[3-[3,5-di-tert-butyl-4-hydroxyphenyl]propionyl]]propionohydrazide (which goes by the trade name Ciba® IRGANOX® MD 1024) or Pentaerythritol Tetrakis(3-(3,5-di-tert-butyl-4-hydroxyphenyl)propionate) (which goes by the trade name Ciba® IRGANOX® 1010). In some embodiments, between 0.5-5% antioxidant improves the long term stability of the filler material.

In some embodiments, as described above, the layer of carbon nanotubes can withstand a shearing force of at least 0.5 Kgf without detaching from the copper substrate. In some embodiments, the layer of carbon nanotubes can withstand a shearing force of at least 3.3 Kgf without detaching from the copper substrate. In some embodiments, the layer of carbon nanotubes can withstand a shearing force of at least 5 Kgf without detaching from the copper substrate.

In some embodiments, as described above, the layer of carbon nanotubes can withstand an interfacial shearing stress of at least 30 psi without detaching from the copper substrate. In some embodiments, the layer of carbon nanotubes can withstand an interfacial shearing stress of at least 200 psi without detaching from the copper substrate. In some embodiments, the layer of carbon nanotubes can withstand an interfacial shearing stress of at least 300 psi without detaching from the copper substrate.

In some embodiments, as described above with respect to FIG. 6, the value of the summation of the bulk thermal resistance and the two contact resistances associated with the thermal interface material changes (e.g., increases) by less than a predetermined value (e.g., 5%, 10%, or 15%) after an article containing the thermal interface material is subjected to one or more harsh environments (e.g., thermal cycling 604, HAST 606, high temperature storage 608, preconditioning 610, shock 612, and/or vibration 614). The two contact resistances associated with the thermal interface material are the contact resistance between the thermal interface material and the copper substrate, and the contact resistance between the thermal interface material and a solid-state device (e.g., an IC) or the equivalent of a solid-state device for testing purposes (e.g. a TTV or a copper block, as discussed above).

In some embodiments, an integrated circuit or other solid-state device may be removably connected to the thermal interface material 120. In some embodiments, the thermal interface material 120 is configured to enable an integrated circuit or other solid-state device to be connected to the thermal interface material, disconnected from the thermal interface material, and then reconnected to the thermal interface material.

In some embodiments, a Raman spectrum of the layer of carbon nanotubes has a D peak at ˜1350 cm⁻¹ with an intensity I_{D}, a G peak at ˜1585 cm⁻¹ with an intensity I_{G}, and an intensity ratio I_{D}/I_{G} of less than 0.7 at a laser excitation wavelength of 514 nm. In some embodiments, the intensity ratio I_{D}/I_{G} is less than 0.6.

In some embodiments, the article of manufacture 1300 is a computer, such as a server computer, client computer, desktop computer, laptop computer, handheld computer, personal digital assistant, cell phone, gaming console, or handheld gaming device.

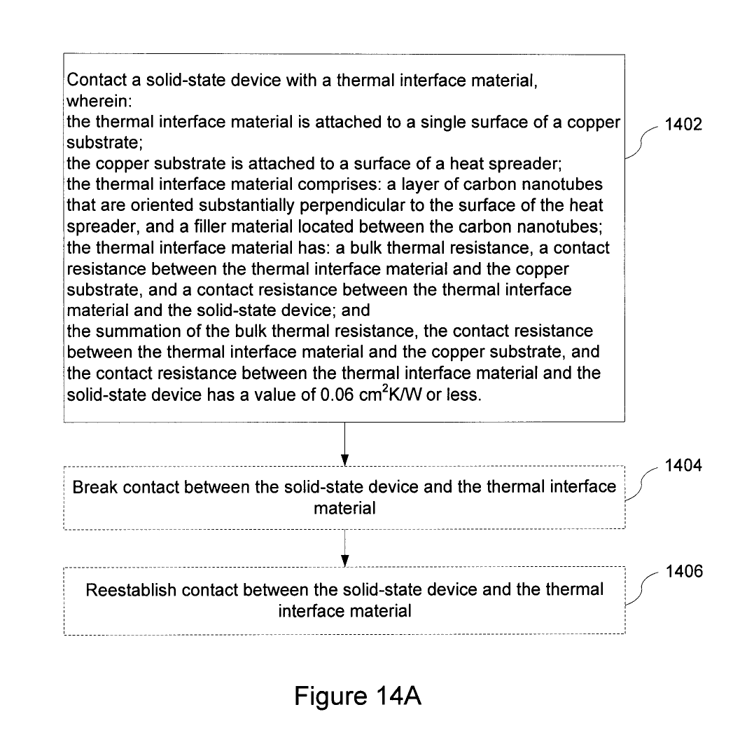

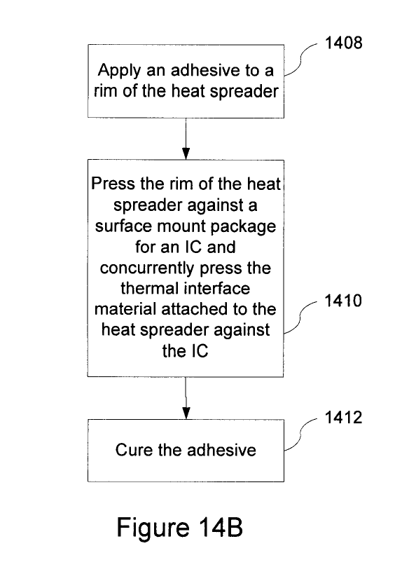

FIG. 14A is a flow diagram illustrating a process for contacting (1402) a solid-state device (e.g., integrated circuit 1310) with a thermal interface material 120 in accordance with some embodiments. The thermal interface material 120 is attached to a single surface of a copper substrate 102. The copper substrate 102 is attached to a surface of a heat spreader 902.

The thermal interface material 120 comprises: a layer 112 of carbon nanotubes 116 that are oriented substantially perpendicular to the surface of the heat spreader, and a filler material 118 located between the carbon nanotubes.

The thermal interface material 120 has: a bulk thermal resistance, a contact resistance between the thermal interface material and the copper substrate, and a contact resistance between the thermal interface material and the solid-state device. The summation of the bulk thermal resistance, the contact resistance between the thermal interface material and the copper substrate, and the contact resistance between the thermal interface material and the solid-state device has a value of 0.06 cm²K/W or less. In some embodiments, the summation has a value of 0.03 cm²K/W or less. In some embodiments, the summation has a value of 0.02 cm²K/W or less. In some embodiments, the summation has a value between 0.02-0.06 cm²K/W. These values are better than what is achieved with conventional thermal interface materials and with prior thermal interface materials that include a layer of carbon nanotubes on a single surface of a copper substrate.

In some embodiments, a Raman spectrum of the layer of carbon nanotubes has a D peak at ˜1350 cm⁻¹ with an intensity I_{D}, a G peak at ˜1585 cm⁻¹ with an intensity I_{G}, and an intensity ratio I_{D}/I_{G} of less than 0.7 at a laser excitation wavelength of 514 nm. In some embodiments, the intensity ratio I_{D}/I_{G} is less than 0.6.

The heat spreader 902 and thermal interface material 120 may be reworkable, which increases yields and reduces manufacturing costs. In some embodiments, contact between the solid-state device and the thermal interface material 120 is broken (1404), and then contact between the solid-state device and the thermal interface material is reestablished (1406).

FIG. 14B is a flow diagram illustrating a process for contacting an integrated circuit 1310 with a thermal interface material 120 in accordance with some embodiments. In some embodiments, the contacting comprises:

applying (1408) an adhesive to a rim (e.g., 220 or 920) of the heat spreader;

pressing (1410) the rim of the heat spreader against a surface mount package for an integrated circuit (e.g., a ball grid array (BGA) package) and concurrently pressing the thermal interface material attached to the heat spreader against the integrated circuit; and

curing (1412) the adhesive.

In some embodiments, the layer of carbon nanotubes in the thermal interface material is designed to have sufficient compressibility so that the nanotubes contact the entire integrated circuit surface even if there are deviations in the flatness of the integrated circuit surface. For example, if the flatness of the integrated circuit surface being contacted varies by +10 μm, the layer of carbon nanotubes can be made with an average length of 30-50 μm, an average diameter of 100-150 nm, and a Young's Modulus of 30-150 GPa so that the thermal resistance is low (e.g., 0.06 cm²K/W or less) when a pressure of 30-50 psi is applied to the heat spreader.

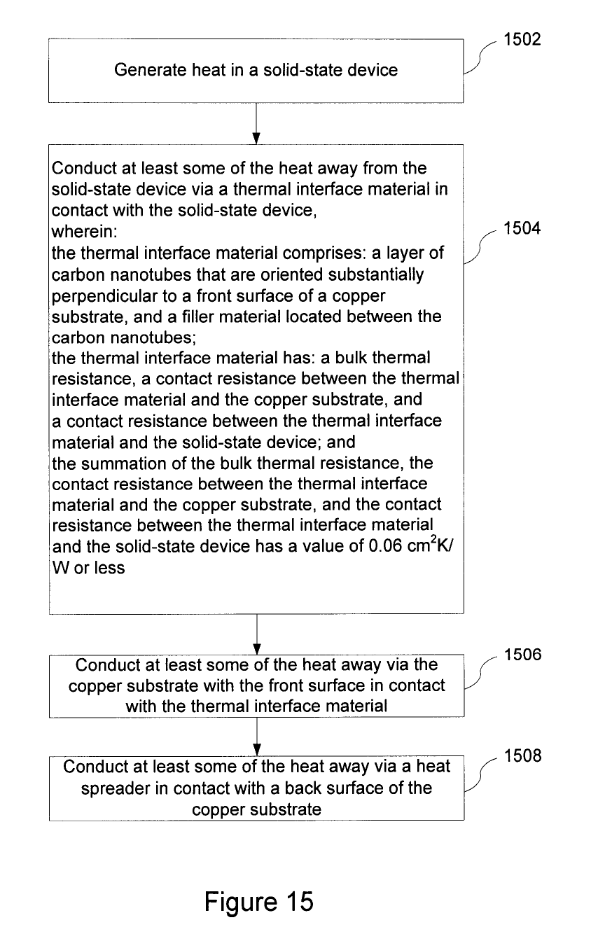

FIG. 15 is a flow diagram illustrating a process for removing heat from a solid-state device (e.g. integrated circuit 1310) in accordance with some embodiments.

Heat is generated (1502) in a solid-state device (e.g., during the use of a computer containing integrated circuit 1310).

At least some of the heat is conducted (1504) away from the solid-state device via a thermal interface material 120 in contact with the solid-state device.

At least some of the heat is conducted (1506) away via a copper substrate 102 with a front surface in contact with the thermal interface material 120.

At least some of the heat is conducted (1508) away via a heat spreader 902 in contact with a back surface of the copper substrate 102.

The thermal interface material 120 comprises: a layer 112 of carbon nanotubes 116 that are oriented substantially perpendicular to the front surface of the copper substrate, and a filler material 118 located between the carbon nanotubes.

The thermal interface material 120 has: a bulk thermal resistance, a contact resistance between the thermal interface material and the copper substrate, and a contact resistance between the thermal interface material and the solid-state device. The summation of the bulk thermal resistance, the contact resistance between the thermal interface material and the copper substrate, and the contact resistance between the thermal interface material and the solid-state device has a vale of 0.06 cm²K/W or less. In some embodiments, the summation has a value of 0.03 cm²K/W or less. In some embodiments, the summation has a value of 0.02 cm²K/W or less. In some embodiments, the summation has a value between 0.02-0.06 cm²K/W. These values are better than what is achieved with conventional thermal interface materials and with prior thermal interface materials that include a layer of carbon nanotubes on a single surface of a copper substrate.

In some embodiments, as described above with respect to FIG. 6, the value of the summation of the bulk thermal resistance and the two contact resistances associated with the thermal interface material changes (e.g., increases) by less than a predetermined value (e.g., 5%, 10%, or 15%) after an article containing the thermal interface material is subjected to one or more harsh environments (e.g., thermal cycling 604, HAST 606, high temperature storage 608, preconditioning 610, shock 612, and/or vibration 614). The two contact resistances associated with the thermal interface material are the contact resistance between the thermal interface material and the copper substrate, and the contact resistance between the thermal interface material and a solid-state device (e.g., an IC) or the equivalent of a solid-state device for testing purposes (e.g. a TTV or a copper block, as discussed above).

In some embodiments, a Raman spectrum of the layer of carbon nanotubes has a D peak at ˜1350 cm⁻¹ with an intensity I_{D}, a G peak at ˜1585 cm⁻¹ with an intensity I_{G}, and an intensity ratio I_{D}/I_{G} of less than 0.7 at a laser excitation wavelength of 514 nm. In some embodiments, the intensity ratio I_{D}/I_{G} is less than 0.6.

The foregoing description, for purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the invention and its practical applications, to thereby enable others skilled in the art to best utilize the invention and various embodiments with various modifications as are suited to the particular use contemplated.

What is claimed is:

1. An article of manufacture, comprising:
a copper substrate with a front surface and a back surface;
a first adhesion layer that contacts the front surface of the copper substrate, wherein the first adhesion layer has a thickness between 200 and 5000 Å and comprises Ti, TiN, Cr, or Ta;
a diffusion barrier layer that contacts the first adhesion layer, wherein the diffusion barrier layer has a thickness between 100 and 400 Å and comprises TiN, SiO₂, Al₂O₃, or TaN;
a catalyst on top of the diffusion barrier layer, wherein the catalyst has a thickness between 30 and 1000 Å and comprises Ni, Fe, or Co; and
a thermal interface material on top of a single surface of the copper substrate;
wherein the thermal interface material comprises:
a layer of carbon nanotubes that contacts the catalyst, and
a filler material located between the carbon nanotubes;
wherein the carbon nanotubes are oriented substantially perpendicular to the front surface of the copper substrate;
wherein the thermal interface material has:
a bulk thermal resistance,
a contact resistance between the thermal interface material and the copper substrate, and
a contact resistance between the thermal interface material and a solid-state device; and
wherein the summation of the bulk thermal resistance, the contact resistance between the thermal interface material and the copper substrate, and the contact resistance between the thermal interface material and the solid-state device has a value of 0.06 cm²K/W or less.

2. An article of manufacture, comprising:
a copper substrate with a front surface and a back surface;
a catalyst on top of a single surface of the copper substrate; and
a thermal interface material on top of the single surface of the copper substrate;
wherein the thermal interface material comprises:
a layer of carbon nanotubes that contacts the catalyst, and
a filler material located between the carbon nanotubes;
wherein the carbon nanotubes are oriented substantially perpendicular to the single surface of the copper substrate;
wherein the thermal interface material has:
a bulk thermal resistance,
a contact resistance between the thermal interface material and the copper substrate, and
a contact resistance between the thermal interface material and a solid-state device; and
wherein the summation of the bulk thermal resistance, the contact resistance between the thermal interface material and the copper substrate, and the contact resistance between the thermal interface material and the solid-state device has a value of 0.06 cm²K/W or less.

3. The article of manufacture of claim 2, wherein the copper substrate has a thickness between 5 and 100 microns.

4. The article of manufacture of claim 2, wherein the copper substrate has a thickness between 5 and 25 microns.

5. The article of manufacture of claim 2, wherein the copper substrate has a thickness between 5 microns and 1 mm.

6. The article of manufacture of claim 2, wherein the filler material located between the carbon nanotubes comprises a phase change material.

7. The article of manufacture of claim 2, wherein the filler material located between the carbon nanotubes comprises an ester, a wax, or an acrylate.

8. The article of manufacture of claim 7, wherein the filler material located between the carbon nanotubes comprises graphene.

9. The article of manufacture of claim 7, wherein the filler material located between the carbon nanotubes comprises an antioxidant.

10. The article of manufacture of claim 2, wherein the filler material located between the carbon nanotubes has a viscosity between 0.5-100 cSt at 25° C., a melting point between 40-80° C., a modulus between 50-1000 psi, and a surface tension between 1-100 dyne/cm.

11. The article of manufacture of claim 2, wherein the filler material located between the carbon nanotubes has a viscosity between 0.5-10 cSt at 25° C., a melting point between 50-60° C., a modulus between 50-150 psi, a surface tension between 1-20 dyne/cm, and a boiling point of at least 250° C.

12. The article of manufacture of claim 2, wherein the filler material located between the carbon nanotubes comprises a mixture of esters, waxes, and/or acrylates.

13. The article of manufacture of claim 2, wherein the filler material located between the carbon nanotubes comprises a mixture of acrylates.

14. The article of manufacture of claim 2, wherein the filler material located between the carbon nanotubes comprises a mixture of methyl acrylate, octadecyl acrylate, and acrylic acid.

15. The article of manufacture of claim 2, wherein the filler material located between the carbon nanotubes comprises a mixture of 0-50% methyl acrylate, 50-90% octadecyl acrylate, and 0-10% acrylic acid.

16. The article of manufacture of claim 2, wherein the filler material located between the carbon nanotubes comprises a mixture of 27% methyl acrylate, 70% octadecyl acrylate, and 3% acrylic acid.

17. The article of manufacture of claim 2, wherein the layer of carbon nanotubes is attached to the copper substrate and can withstand a shearing force of at least 0.5 Kgf without detaching from the copper substrate.

18. The article of manufacture of claim 2, wherein the layer of carbon nanotubes is attached to the copper substrate and can withstand a shearing force of at least 3.3 Kgf without detaching from the copper substrate.

19. The article of manufacture of claim 2, wherein the layer of carbon nanotubes is attached to the copper substrate and can withstand a shearing force of at least 5 Kgf without detaching from the copper substrate.

20. The article of manufacture of claim 2, wherein the layer of carbon nanotubes is attached to the copper substrate and can withstand an interfacial shearing stress of at least 30 psi without detaching from the copper substrate.

21. The article of manufacture of claim 2, wherein the layer of carbon nanotubes is attached to the copper substrate and can withstand an interfacial shearing stress of at least 200 psi without detaching from the copper substrate.

22. The article of manufacture of claim 2, wherein the layer of carbon nanotubes is attached to the copper substrate and can withstand an interfacial shearing stress of at least 300 psi without detaching from the copper substrate.

23. The article of manufacture of claim 2, wherein the value of the summation of the bulk thermal resistance, the contact resistance between the thermal interface material and the copper substrate, and the contact resistance between the thermal interface material and the solid-state device changes by less than 10% when the article of manufacture is cycled from −40° C. to 125° C. with a 25° C./min ramp and 5 minute dwell times for 1000 cycles.

24. The article of manufacture of claim 2, wherein the value of the summation of the bulk thermal resistance, the contact resistance between the thermal interface material and the copper substrate, and the contact resistance between the thermal interface material and the solid-state device changes by less than 10% when the article of manufacture is heated at 120° C. for 96 hours in 85% relative humidity.

25. The article of manufacture of claim 2, wherein the value of the summation of the bulk thermal resistance, the contact resistance between the thermal interface material and the copper substrate, and the contact resistance between the thermal interface material and the solid-state device changes by less than 10% when the article of manufacture is heated at 150° C. for 1000 hours.

26. The article of manufacture of claim 2, wherein the value of the summation of the bulk thermal resistance, the contact resistance between the thermal interface material and the copper substrate, and the contact resistance between the thermal interface material and the solid-state device changes by less than 10% when the article of manufacture is: cycled from −40° C. to 125° C. with a 10° C./min ramp and 10 minute dwell times for 5 cycles, then heated at 125° C. for 24 hours, then heated at 30° C. for 192 hours in 60% relative humidity, and then cycled from 25° C. to 260° C. for 3 cycles.

27. The article of manufacture of claim 2, wherein the value of the summation of the bulk thermal resistance, the contact resistance between the thermal interface material and the copper substrate, and the contact resistance between the thermal interface material and the solid-state device changes by less than 10% when the article of manufacture is subjected to a variable frequency vibration comprising 4 4-minute cycles from 20 Hz to 2000 Hz and back to 20 Hz performed in each of three orthogonal orientations with a peak acceleration of 20 G.

28. The article of manufacture of claim 2, wherein the value of the summation of the bulk thermal resistance, the contact resistance between the thermal interface material and the copper substrate, and the contact resistance between the thermal interface material and the solid-state device changes by less than 10% when the article of manufacture is subjected to Gaussian random vibration with 1.11 G root mean square (RMS) acceleration, 1.64 in/sec RMS velocity, 0.0310 inches RMS displacement, and 0.186 three sigma peak-to-peak displacement for 30 minutes in each of three orthogonal axes.

29. The article of manufacture of claim 2, wherein the value of the summation of the bulk thermal resistance, the contact resistance between the thermal interface material and the copper substrate, and the contact resistance between the thermal interface material and the solid-state device changes by less than 10% when the article of manufacture is subjected to a mechanical shock of 1500 G in a 0.5 ms, half sine wave pulse, with 5 such shocks applied along 6 different axes.

30. The article of manufacture of claim 2, wherein the copper substrate contains less than 40 ppm oxygen.

31. The article of manufacture of claim 2, wherein the copper substrate contains 10 ppm oxygen or less.

32. The article of manufacture of claim 2, wherein the copper substrate is oxygen-free copper.

33. The article of manufacture of claim 2, wherein the copper substrate has a cross-sectional area that substantially corresponds to the cross-sectional area of the solid-state device.

34. The article of manufacture of claim 33, wherein the solid-state device is a light emitting diode, laser, power transistor, RF device, or solar cell.

35. The article of manufacture of claim 2, wherein the copper substrate has a cross-sectional area that substantially corresponds to the cross-sectional area of an integrated circuit.

36. The article of manufacture of claim 2, including a first adhesion layer that contacts the single surface of the copper substrate.

37. The article of manufacture of claim 36, wherein the first adhesion layer has a thickness between 200 and 5000 Å and comprises Ti, TiN, Cr, or Ta.

38. The article of manufacture of claim 36, wherein the first adhesion layer has a thickness between 200 and 500 Å and comprises Ti.

39. The article of manufacture of claim 36, including a diffusion barrier layer on top of the first adhesion layer.

40. The article of manufacture of claim 39, wherein the diffusion barrier layer has a thickness between 100 and 400 Å and comprises TiN, SiO₂, Al₂O₃, or TaN.

41. The article of manufacture of claim 39, wherein the diffusion barrier layer has a thickness between 100 and 400 Å and comprises TiN.

42. The article of manufacture of claim 39, including a second adhesion layer between the diffusion barrier layer and the catalyst.

43. The article of manufacture of claim 42, wherein the second adhesion layer has a thickness between 25 and 400 Å and comprises Ti, SiO₂, TiN, Al₂O₃, or Mo.

44. The article of manufacture of claim 42, wherein the second adhesion layer has a thickness between 25 and 200 Å and comprises Ti.

45. The article of manufacture of claim 2, wherein the catalyst has a thickness between 30 and 1000 Å and comprises Ni, Fe, or Co.

46. The article of manufacture of claim 2, wherein the catalyst has a thickness between 200 and 400 Å and comprises Ni.

47. The article of manufacture of claim 2, wherein the carbon nanotubes have an average diameter between 60 nm and 200 nm.

48. The article of manufacture of claim 47, wherein the carbon nanotubes have a tip density between 10 and 40 nanotubes per dm².

49. The article of manufacture of claim 2, wherein the carbon nanotubes have an average diameter between 100 nm and 150 nm.

50. The article of manufacture of claim 2, wherein the carbon nanotubes have a surface area coverage density between 15 and 40 percent.

51. The article of manufacture of claim 2, wherein the carbon nanotubes comprise multiwalled carbon nanotubes.

52. The article of manufacture of claim 2, wherein substantially all of the carbon nanotubes are individually separated from each other.

53. The article of manufacture of claim 2, wherein the carbon nanotubes have an average length between 5 and 50 μm.

54. The article of manufacture of claim 2, wherein the carbon nanotubes have an average length between 20 and 45 μm.

55. The article of manufacture of claim 2, wherein a Raman spectrum of the layer of carbon nanotubes has a D peak at ˜1350 cm⁻¹ with an intensity I_{D}, a G peak at ˜1585 cm⁻¹ with an intensity I_{G}, and an intensity ratio I_{D}/I_{G} of less than 0.7 at a laser excitation wavelength of 514 nm.

56. The article of manufacture of claim 2, wherein the Raman spectrum of the layer of carbon nanotubes has a D peak at ˜1350 cm⁻¹ with an intensity I_{D}, a G peak at ˜1585 cm⁻¹ with an intensity I_{G}, and an intensity ratio I_{D}/I_{G} of less than 0.6 at a laser excitation wavelength of 514 nm.

57. The article of manufacture of claim 2, wherein the solid-state device is an integrated circuit.

58. The article of manufacture of claim 2,
wherein the summation of the bulk thermal resistance, the contact resistance between the thermal interface material and the copper substrate, and the contact resistance between the thermal interface material and the solid-state device has a value of 0.03 cm²K/W or less.

59. The article of manufacture of claim 58, wherein the solid-state device is an integrated circuit.

60. The article of manufacture of claim 2,
wherein the summation of the bulk thermal resistance, the contact resistance between the thermal interface material and the copper substrate, and the contact resistance between the thermal interface material and the solid-state device has a value between 0.02-0.06 cm²K/W.

61. The article of manufacture of claim 60, wherein the solid-state device is an integrated circuit.

62. The article of manufacture of claim 2, wherein the solid-state device may be removably connected to the thermal interface material.

63. The article of manufacture of claim 62, wherein the solid-state device is an integrated circuit.

64. The article of manufacture of claim 2, wherein the thermal interface material is configured to enable a solid-state device to be connected to the thermal interface material, disconnected from the thermal interface material, and then reconnected to the thermal interface material.

65. The article of manufacture of claim 64, wherein the solid-state device is an integrated circuit.

66. The article of manufacture of claim 2, wherein the article of manufacture is configured to be reused to cool a succession of solid-state devices.

67. The article of manufacture of claim 66, wherein the solid-state devices are integrated circuits.

68. A method, comprising:
generating heat in a solid-state device; and
conducting at least some of the heat away from the solid-state device via a thermal interface material in contact with the solid-state device,
wherein:
the thermal interface material is attached to a single surface of a copper substrate;
the thermal interface material comprises:
a layer of carbon nanotubes that are oriented substantially perpendicular to the single surface of the copper substrate, and
a filler material located between the carbon nanotubes;
the thermal interface material has:
a bulk thermal resistance,
a contact resistance between the thermal interface material and the copper substrate, and
a contact resistance between the thermal interface material and the solid-state device; and
the summation of the bulk thermal resistance, the contact resistance between the thermal interface material and the copper substrate, and the contact resistance between the thermal interface material and the solid-state device has a value of 0.06 cm²K/W or less.

69. An article of manufacture, comprising:
a heat spreader;
a copper substrate with a front surface and a back surface, wherein the back surface is bonded to the heat spreader; and
a thermal interface material attached to the front surface of the copper substrate comprising a layer of carbon nanotubes and a filler material located between the carbon nanotubes;
wherein the carbon nanotubes are oriented substantially perpendicular to the front surface of the copper substrate;
wherein the thermal interface material has:
a bulk thermal resistance,
a contact resistance between the thermal interface material and the front surface of the copper substrate, and
a contact resistance between the thermal interface material and a solid-state device; and
wherein the summation of the bulk thermal resistance, the contact resistance between the thermal interface material and the copper substrate, and the contact resistance between the thermal interface material and the solid-state device has a value of 0.06 cm²K/W or less.

70. An article of manufacture, comprising:
a solid-state device;
a heat spreader;
a copper substrate with a front surface and a back surface, wherein the back surface is bonded to the heat spreader; and
a thermal interface material attached to the front surface of the copper substrate and contacting the solid-state device;
wherein the thermal interface material comprises a layer of carbon nanotubes and a filler material located between the carbon nanotubes;
wherein the carbon nanotubes are oriented substantially perpendicular to the front surface of the copper substrate;
wherein the thermal interface material has:
a bulk thermal resistance,
a contact resistance between the thermal interface material and the copper substrate, and
a contact resistance between the thermal interface material and the solid-state device; and
wherein the summation of the bulk thermal resistance, the contact resistance between the thermal interface material and the copper substrate, and the contact resistance between the thermal interface material and the solid-state device has a value of 0.06 cm²K/W or less.

71. The article of manufacture of claim 70, wherein the solid-state device is an integrated circuit.

72. The article of manufacture of claim 70, wherein the article of manufacture is a computer.

73. The article of manufacture of claim 70, wherein the solid-state device may be removably connected to the thermal interface material.

74. The article of manufacture of claim 73, wherein the solid-state device is an integrated circuit.

75. The article of manufacture of claim 70, wherein the thermal interface material is configured to enable a solid-state device to be connected to the thermal interface material, disconnected from the thermal interface material, and then reconnected to the thermal interface material.
